(19) United States
(12) Patent Application Publication
(10) Pub. No.: US 2025/0311595 A1
(43) Pub. Date: Oct. 2, 2025

(54) DISPLAY DEVICE

(71) Applicant: Samsung Display Co., Ltd., Yongin-si (KR)

(72) Inventors: SUNKWANG KIM, Yongin-si (KR); KANGMOON JO, Yongin-si (KR); SEONGYOUNG LEE, Yongin-si (KR); YONGJAE JANG, Yongin-si (KR); JAE HYUK JANG, Yongin-si (KR)

(21) Appl. No.: 19/008,172

(22) Filed: Jan. 2, 2025

(30) Foreign Application Priority Data
Mar. 29, 2024 (KR) 10-2024-0043147

(51) Int. Cl. H10K 59/80; H10K 59/126; H10K 59/38

(52) U.S. Cl. CPC H10K 59/873; H10K 59/38; H10K 59/126

(57) ABSTRACT

A display device includes a display panel, which includes a plurality of unit regions each including a plurality of pixel regions and a transmission region adjacent to the plurality of pixel regions and provides a source light, and an optical layer on the display panel and transmits the source light or converts the source light into light of a different wavelength. The plurality of unit regions include a first unit region and a second unit region adjacent to each other along a second direction, each including a plurality of pixel regions and a transmission region adjacent to the plurality of pixel regions along a first direction crossing the second direction. A first middle region is defined between the transmission regions. The optical layer includes a blocking pattern that overlaps the first middle region in a plan view of the display device.

### CROSS-REFERENCE TO RELATED APPLICATION

The present application claims priority to and the benefit of Korean Patent Application No. 10-2024-0043147, filed on Mar. 29, 2024, in the Korean Intellectual Property Office, the entire disclosure of which is incorporated herein by reference.

### BACKGROUND

### 1. Field

The present disclosure herein relates to a display device, for example, to a display device having improved transmittance and durability.

### 2. Description of the Related Art

Multimedia devices such as televisions, mobile phones, tablets, navigation systems, and/or game consoles are equipped with display devices that present (display) images to users via a display screen. These display devices may include (be composed of) a display panel that generates an image and an optical layer with a light control pattern designed to enhance (improve) the light output efficiency of the display panel. The light control pattern may selectively transmit source light within specific wavelength ranges or alter (change) the color of the source light. Additionally, certain light control patterns may modify (change) the properties (characteristics) of light without altering (changing) its color (i.e., the color of the source light).

Recently, technological advancements have enabled (led to) the creation (development) of transparent display devices, which incorporate (feature) transparent transmission regions within their display regions (display areas).

### SUMMARY

An aspect according to one or more embodiments of the present disclosure is directed toward a display device having improved durability by preventing or reducing defects while improving the transmittance of a display region. Additional aspects of embodiments will be set forth in part in the description, which follows and, in part, will be apparent from the description, or may be learned by practice of the presented embodiments of the disclosure.

A display device according to one or more embodiments includes a display panel, which includes a plurality of unit regions each including a plurality of pixel regions and a transmission region adjacent to the plurality of pixel regions and provides (e.g., is to provide) source light, and an optical layer on the display panel and transmits (e.g., is to transmit) the source light or converts (e.g., or is to convert) the source light into light of a different wavelength. The plurality of unit regions include a first unit region including a plurality of first pixel regions and a first transmission region adjacent to the plurality of first pixel regions along a first direction and a second unit region adjacent to the first unit region along a second direction crossing the first direction and including a plurality of second pixel regions and a second transmission region adjacent to the plurality of second pixel regions along the first direction. The first transmission region and the second transmission region are adjacent to each other along the second direction, and a first middle region is defined between the first transmission region and the second transmission region. The optical layer includes a blocking pattern that overlaps (e.g., at least) the first middle region on a plane (e.g., in a plan view of the display device).

In one or more embodiments, the optical layer may further include a light control layer. The light control layer may include a bank on the display panel and has a plurality of bank openings respectively corresponding to the plurality of pixel regions, and a plurality of light control patterns respectively arranged inside the plurality of bank openings.

In one or more embodiments, the bank may further include an open portion corresponding to the transmission region. At least a portion of the blocking pattern may be arranged within the open portion.

In one or more embodiments, the blocking pattern may include a blocking portion arranged within the open portion and a spacer portion overlapping the bank on a plane (e.g., in a plan view). The blocking portion and the spacer portion may include a same material.

In one or more embodiments, the spacer portion and the blocking portion may be connected to each other to have an integral shape. That is, the spacer portion and the blocking portion may be integrally connected to form a single integral unit.

In one or more embodiments, the blocking portion may be spaced and/or apart (e.g., spaced apart or separated) from an inner side surface of the bank defining a transmission opening.

In one or more embodiments, the thickness of the blocking pattern may be smaller than the thickness of the bank.

In one or more embodiments, the optical layer may further include a color filter layer arranged on the light control layer and including a plurality of color filters.

In one or more embodiments, the plurality of unit regions may further include: a third unit region adjacent to the first unit region along the first direction and including a plurality of third pixel regions and a third transmission region adjacent to the plurality of third pixel regions along the first direction; and a fourth unit region adjacent to the third unit region along the second direction and including a plurality of fourth pixel regions and a fourth transmission region adjacent to the plurality of fourth pixel regions along the first direction. The third transmission region and the fourth transmission region may be adjacent to each other along the second direction, and a second middle region may be defined between the third transmission region and the fourth transmission region. The blocking pattern may include a first blocking pattern overlapping the first middle region and a second blocking pattern overlapping the second middle region.

In one or more embodiments, the plurality of unit regions may further include: a fifth unit region adjacent to the second unit region along the second direction and including a plurality of fifth pixel regions and a fifth transmission region adjacent to the plurality of fifth pixel regions along the first direction; and a sixth unit region adjacent to the fifth unit region along the first direction and including a plurality of sixth pixel regions and a sixth transmission region adjacent to the plurality of sixth pixel regions along the first direction. The second transmission region and the fifth transmission region may be adjacent to each other along the second direction, and a third middle region may be defined between the second transmission region and the fifth transmission region. The blocking pattern may not overlap the third middle region.

In one or more embodiments, the fourth transmission region and the sixth transmission region may be adjacent to each other along the second direction, and a fourth middle region may be defined between the fourth transmission region and the sixth transmission region. The blocking pattern may include a first blocking pattern overlapping the first middle region and a third blocking pattern overlapping the fourth middle region.

In one or more embodiments, the blocking pattern may include an optically transparent material.

In one or more embodiments, the plurality of pixel regions may include a first sub-pixel region, a second sub-pixel region, and a third sub-pixel region sequentially arranged along the second direction. The transmission region may overlap each of the first sub-pixel region, the second sub-pixel region, and the third sub-pixel region in the first direction.

In one or more embodiments of the disclosure, the display device may further include a filler between the display panel and the optical layer.

In one or more embodiments, the display panel may include: a plurality of light-emitting elements that generate the source light; and signal lines at least partially electrically connected to the plurality of light-emitting elements. At least some of the signal lines may overlap the blocking pattern on a plane (e.g., in a plan view).

In one or more embodiments, the display panel may further include an encapsulation layer covering the plurality of light-emitting elements. The encapsulation layer may include at least one inorganic encapsulation film and at least one organic encapsulation film.

In one or more embodiments, the display panel may further include a pixel defining film having a transmission opening corresponding to the transmission region and a light-emitting opening in which each of the plurality of light-emitting elements is arranged.

In one or more embodiments of the disclosure, a display device includes a display panel, which includes a plurality of unit regions each including a plurality of pixel regions and a transmission region adjacent to the plurality of pixel regions and provides (e.g., is to provide) a source light, and an optical layer on the display panel and transmits (e.g., is to transmit) the source light or converts (e.g., is to convert) the source light into light of a different wavelength. The plurality of unit regions include: a first unit region including a plurality of first pixel regions and a first transmission region adjacent to the plurality of first pixel regions along a first direction; and a second unit region adjacent to the first unit region along a second direction crossing the first direction and including a plurality of second pixel regions and a second transmission region adjacent to the plurality of second pixel regions along the first direction. The optical layer includes: a light control layer including a bank, the bank having a plurality of bank openings respectively corresponding to the plurality of pixel regions and an open portion corresponding to the transmission region, and a plurality of light control patterns respectively arranged inside the plurality of bank openings; and a blocking pattern at least partially arranged within the open portion and arranged between the first transmission region and the second transmission region on a plane (e.g., in a plan view).

In one or more embodiments of the disclosure, a display device includes a display panel, which includes a plurality of unit regions each including a plurality of pixel regions and a transmission region adjacent to the plurality of pixel regions and provides (e.g., is to provide) a source light, and an optical layer on the display panel and transmits (e.g., is to transmit) the source light or converts (e.g., is to convert) the source light into light of a different wavelength. The plurality of unit regions include a first unit region including a plurality of first pixel regions and a first transmission region adjacent to the plurality of first pixel regions along a first direction and a second unit region adjacent to the first unit region along a second direction crossing the first direction and including a plurality of second pixel regions and a second transmission region adjacent to the plurality of second pixel regions along the first direction. The optical layer includes: a bank having a plurality of bank openings respectively corresponding to the plurality of pixel regions and an open portion corresponding to the transmission region; and a blocking pattern partially arranged between the first transmission region and the second transmission region on a plane (e.g., in a plan view). The blocking pattern includes a blocking portion between the first transmission region and the second transmission region on a plane (e.g., in a plan view) and a spacer portion overlapping the bank on a plane (e.g., in a plan view) and including the same material as the blocking portion.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1A is a perspective view of an electronic device according to one or more embodiments of the disclosure;

FIG. 1B is a perspective view of a curved electronic device according to one or more embodiments of the disclosure;

FIG. 2 is a cross-sectional view of a display device according to one or more embodiments of the disclosure;

FIG. 3 is a plan view of the display device according to one or more embodiments of the disclosure;

FIG. 4 is an equivalent circuit diagram of a pixel according to one or more embodiments of the disclosure;

FIG. 5A is an enlarged plan view of a portion of a display region of the display device according to one or more embodiments of the disclosure;

FIG. 5B is an enlarged plan view of some components of the display device according to one or more embodiments of the disclosure;

FIG. 6 is a cross-sectional view of the display device taken along the line I-I′ of FIG. 5A;

FIG. 7 is a cross-sectional view of the display device taken along the line II-II′ of FIG. 5A;

FIG. 8 is a cross-sectional view of a light-emitting element according to one or more embodiments of the disclosure;

FIG. 9A is a cross-sectional view of some components of an optical layer according to one or more embodiments of the disclosure;

FIG. 9B is a cross-sectional view of some components of an optical layer according to one or more embodiments of the disclosure;

FIG. 10 is a cross-sectional view of some components of an optical layer according to one or more embodiments of the disclosure;

FIG. 11 is a cross-sectional view of a portion of a display device according to one or more embodiments of the disclosure; and

FIG. 12A is an enlarged plan view of some components of the display device according to one or more embodiments of the disclosure; and

FIG. 12B is an enlarged plan view of some components of the display device according to one or more embodiments of the disclosure.

### DETAILED DESCRIPTION

Hereinafter, embodiments of the disclosure will be described with reference to the drawings. In this specification, it will be understood that if (e.g., when) an element (or region, layer, portion, and/or the like) is referred to as being “on”, “connected to” or “coupled to” another element, it can be directly on, connected or coupled to the other element, or intervening elements may be present between them.

Like reference numerals refer to like elements throughout, and duplicative descriptions thereof may not be provided. In addition, in the drawings, the thicknesses, ratios, and dimensions of elements may be exaggerated for effective description of the technical contents. As used herein, the term “and/or” includes any and all combinations that the associated configurations can define.

It will be understood that, although the terms first, second, and/or the like, may be used herein to describe one or more suitable elements, these elements should not be limited by these terms. These terms are only used to distinguish one element from another element. For example, a first element could be termed a second element without departing from the scope of the disclosure. Similarly, the second element may also be referred to as the first element. The terms of a singular form include plural forms unless otherwise specified.

In addition, terms, such as “below”, “lower”, “above”, “upper” and/or the like, are used herein for ease of description to describe one element's relation to another element(s) as illustrated in the drawings. The above terms are relative concepts and are described based on the directions indicated in the drawings.

It will be understood that the terms “include” and/or “have”, if (e.g., when) used in this specification, specify the presence of stated features, integers, steps, operations, elements, components and/or groups thereof, but do not preclude the presence or addition of one or more other features, integers, steps, operations, elements, components, and/or groups thereof.

In the present application, being “directly arranged” may refer to that there is no layer, film, region, plate, and/or the like added between a part such as a layer, film, region, or plate and another part such as a layer, film, region, or plate. For example, being “directly arranged” may refer to that no additional member such as an adhesive member is arranged between two layers or two members. That is, it will be understood that when an element or layer is referred to as being “on”, “connected to”, “coupled to”, or “adjacent to” another element or layer, it can be directly on, connected to, coupled to, or adjacent to the other element or layer, or one or more intervening elements or layers may be present. In contrast, when an element or layer is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display device according to one or more embodiments of the disclosure will be described with reference to the accompanying drawings.

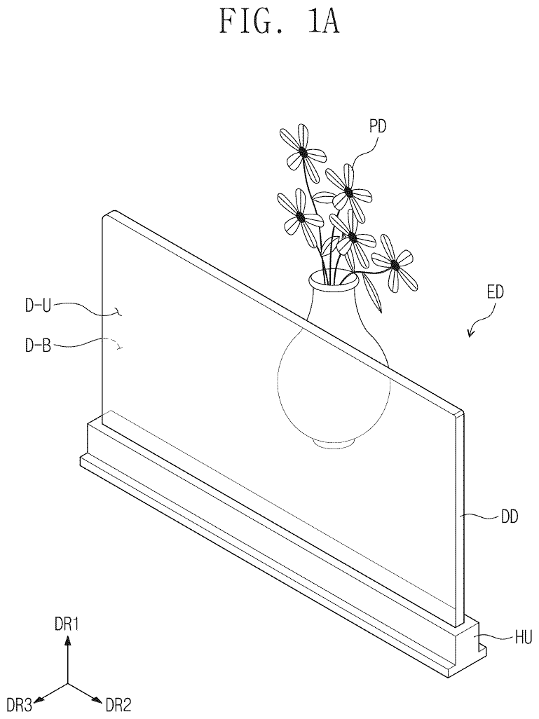

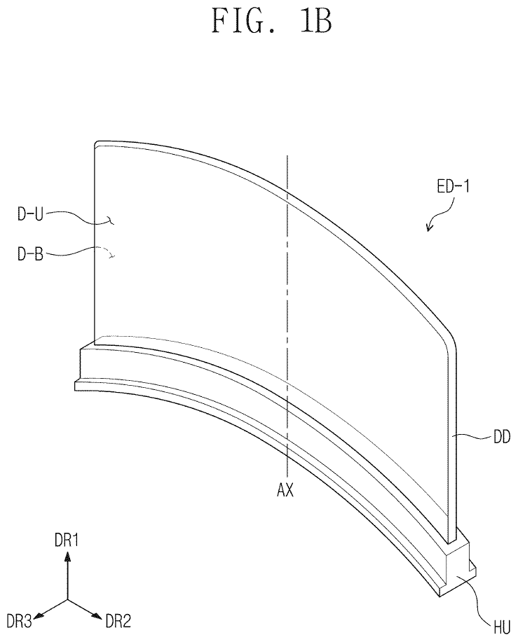

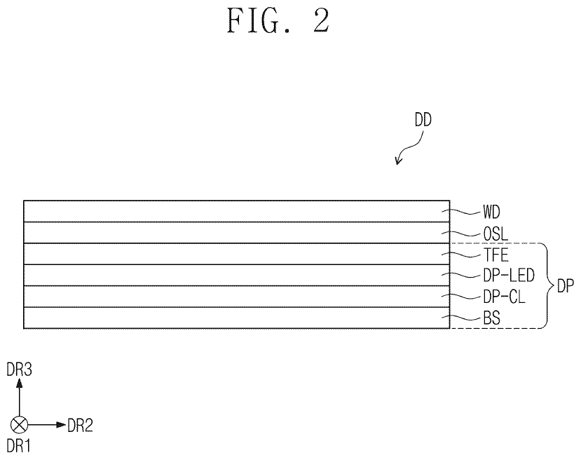

FIG. 1A is a perspective view of an electronic device according to one or more embodiments of the disclosure. FIG. 1B is a perspective view of a curved electronic device according to one or more embodiments of the disclosure. FIG. 2 is a cross-sectional view of a display device according to one or more embodiments of the disclosure.

Electronic devices ED and ED-1 illustrated in FIGS. 1A and 1B may include a display device DD and a housing HU that accommodates at least a portion of the display device DD. For example, a lower portion of the display device DD may be accommodated in the housing HU.

Referring to FIG. 1A, the display device DD may display an image through a front surface D-U. The upper surface of a member arranged on the uppermost side (e.g., along a thickness direction) of the display device DD may be defined as the front surface D-U of the display device DD. According to this disclosure, the upper surface of a window WD illustrated in FIG. 2 may be defined as the front surface D-U of the display device DD.

In this embodiment, the front surface D-U is parallel to a plane defined by a first direction DR1 and a second direction DR2. The normal direction of the front surface D-U, that is, the thickness direction of the display device DD is indicated by a third direction DR3. The front (or upper) and rear (or lower) surfaces of each layer or unit described hereinafter are divided by (e.g., defined along) the third direction DR3, and the third direction DR3 is described as an upper direction and the opposite direction of the third direction DR3 is described as a lower direction.

The display device DD according to one or more embodiments of this disclosure may be a transparent display device DD. The transparent display device DD may display information in a state in which an object PD arranged on the rear surface D-B of the display device DD is transparently shown through the front surface D-U of the display device DD. Accordingly, a user may recognize an object arranged on the rear surface D-B of the display device DD from the front surface D-U of the display device DD. The information (being displayed) may include images, contents, playback screens, application execution screens, web browser screens, and one or more suitable graphic objects and is not limited to any one or more embodiments. In

FIG. 1A, a flower vase is illustrated as an example of the object PD, but the object PD is not limited thereto, and as long as it is an object having a specific shape, the object PD is not limited to any one or more embodiments.

The housing HU may protect the display device DD from an external shock and/or intrusion of foreign substances. The housing HU may be made of a material such as plastic or metal. However, this is an example, and one or more embodiments of the disclosure are not limited thereto. The housing HU may be made of any suitable material as long as it can protect the display device DD from an external shock and/or intrusion of foreign substances. In the electronic device ED according to one or more embodiments of the disclosure, the housing HU may not be provided, or the display device DD may be rolled and arranged inside the housing HU by a separate hinge member, and the disclosure is not limited to any one or more embodiments. For example, the display device DD may be arranged inside the housing HU to display information through the housing HU.

Referring to FIG. 1B, the electronic device ED-1 according to one or more embodiments of the disclosure may be curved along the second direction DR2 with respect to a virtual axis AX extending in the first direction DR1. Accordingly, the display device DD may be curved at a set or predetermined curvature, and the housing HU may have a curvature corresponding thereto. The embodiment of the disclosure is not limited thereto, and the axis AX may extend in the second direction DR2 or the display device DD may be curved based on a plurality of axes extending in different directions.

In addition, the display device DD may be a rollable display panel, a foldable display panel, or a slidable display panel, and the entire display device DD may be arranged inside the housing HU in an operating state. Accordingly, the display device DD may include a curved display surface or a three-dimensional display surface. The three-dimensional display surface may include a plurality of display regions indicating (e.g., oriented towards) different directions.

Referring to FIG. 2, the display device DD according to this disclosure may include a display panel DP, an optical layer OSL, and a window WD. The display panel DP may include a base substrate BS, a circuit element layer DP-CL arranged on the base substrate BS, a display element layer DP-LED, and an encapsulation layer TFE. The display device DD may further include functional layers such as an anti-reflection layer and/or a refractive index adjustment layer.

As a light-emitting display panel, the display panel DP may be any one

selected from among a liquid crystal display panel, an electrophoretic display panel, a microelectromechanical system (MEMS) display panel, an electrowetting display panel, an organic light-emitting display panel, an inorganic light-emitting display panel, and a quantum-dot display panel, and one or more embodiments of the disclosure is not particularly limited thereto.

The base substrate BS may include a synthetic resin film (or layer). The synthetic resin layer may include a thermosetting resin. In one or more embodiments, the synthetic resin layer may be a polyimide-based resin layer, and its material is not particularly limited thereto. The synthetic resin layer may include at least one (e.g., at least any one) selected from among an acrylic-based resin, a methacrylic-based resin, polyisoprene, a vinyl-based resin, an epoxy-based resin, a urethane-based resin, a cellulose-based resin, a siloxane-based resin, a polyamide-based resin, and a perylene-based resin. In addition, the base substrate BS (e.g., base layer) may include a glass substrate, a metal substrate, or an organic/inorganic composite material substrate.

The circuit element layer DP-CL includes at least a plurality of insulating layers and a circuit element. The insulating layers described in more detail below may include an organic layer and/or an inorganic layer. In the circuit element layer DP-CL, an insulating layer, a semiconductor layer, and a conductive layer are formed through processes such as coating and deposition. Hereafter, the insulating layer, the semiconductor layer, and the conductive layer may be selectively patterned through photolithography and etching processes. Through these processes, a semiconductor pattern, a conductive pattern, a signal line, and/or the like, are formed. Patterns arranged on a same layer are formed through a same process.

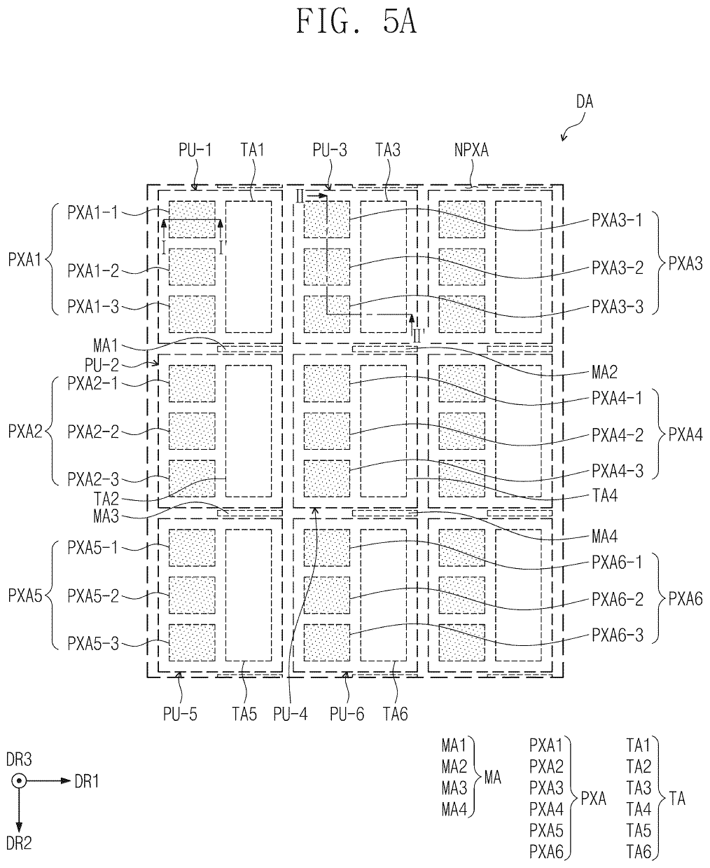

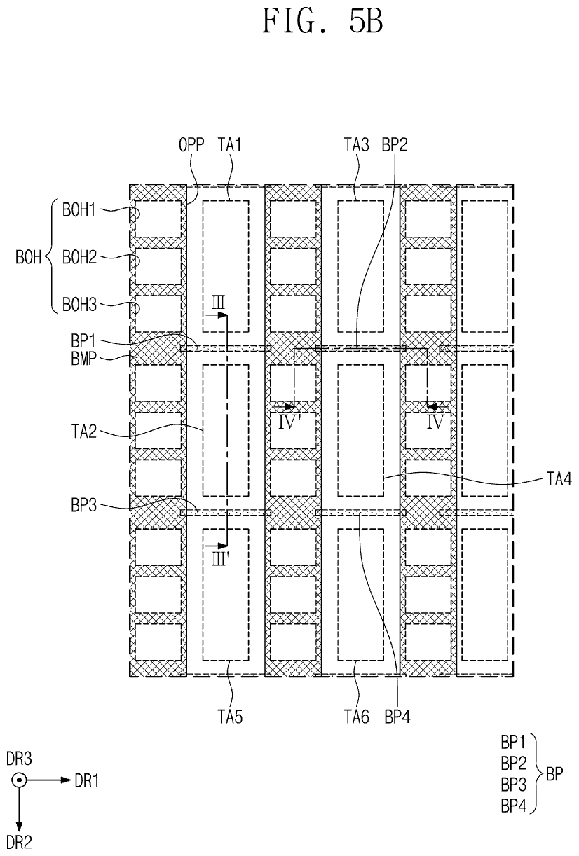

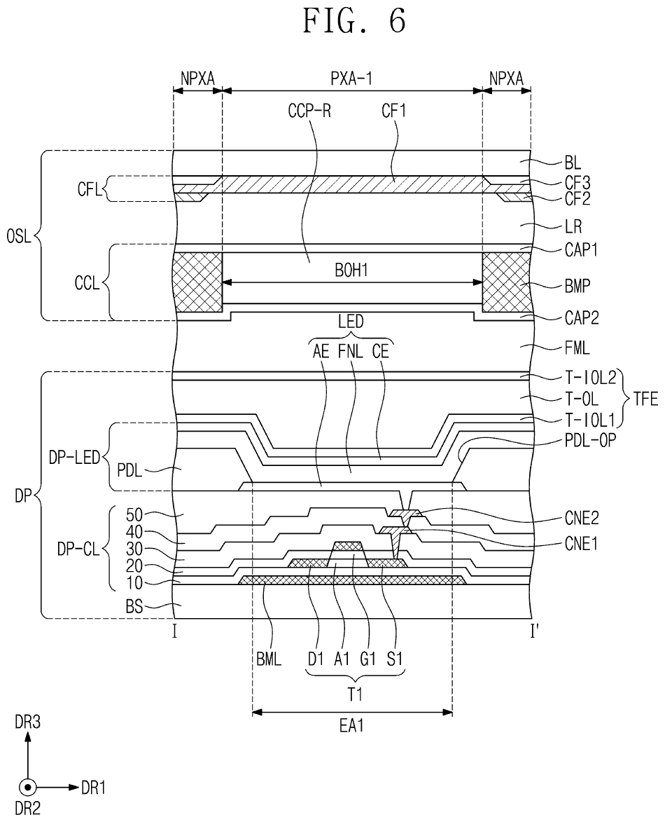

The circuit element layer DP-CL includes signal lines and a driving circuit configured to drive a pixel. The display element layer DP-LED may include a light-emitting element LED (see FIG. 6) included in the pixel and a pixel defining film PDL (see FIG. 5).

The encapsulation layer TFE may be arranged on the display element layer DP-LED and protect the light-emitting element LED. The encapsulation layer TFE may include inorganic encapsulation films and an organic encapsulation film arranged between the inorganic encapsulation films. The inorganic encapsulation films may protect the light-emitting element LED from moisture and oxygen, and the organic encapsulation film may protect the light-emitting element LED from foreign substances such as dust particles.

The optical layer OSL may include light control patterns that may change the optical properties of the source light generated by the light-emitting element LED. In addition, the optical layer OSL may reduce the reflectance of external light incident from the upper side of the window WD. The light control patterns may include quantum dots, and the optical layer OSL may include color filters that selectively transmit light that has passed through the light control patterns.

The window WD may be arranged above the display panel DP and transmit images provided from the display panel DP to the outside. The window WD may include a base layer and functional layers arranged on the base layer. The functional layers may include a protective layer, an anti-fingerprint layer, and/or the like. The base layer of the window WD may be made of glass, sapphire, plastic, and/or the like.

The display device DD according to one or more embodiments of the disclosure may further include an input sensor arranged between the display panel DP and the optical layer OSL. The input sensor may be arranged directly on the display panel DP. The input sensor may sense a user's input, for example, by an electromagnetic induction method and/or a capacitance method. The display panel DP and the input sensor may be formed through a substantially continuous process. Here, being “directly arranged” may refer to that a third component is not arranged between the input sensor and the display panel DP. For example, a separate adhesive layer may not be arranged between the input sensor and the display panel DP.

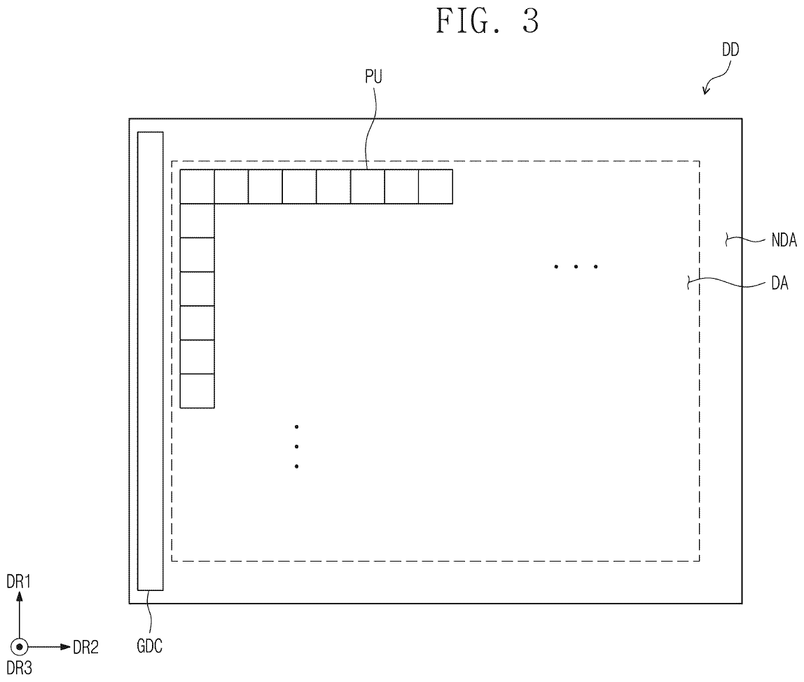

FIG. 3 is a plan view of the display device according to one or more embodiments of the disclosure.

Referring to FIG. 3, the display device DD according to one or more embodiments of the disclosure may include pixels arranged in a unit region PU, a gate driving circuit GDC connected to the pixels, and signal lines.

The display device DD may include a display region DA and a non-display region NDA. A functional layer FNL (see FIG. 6) of the pixels arranged in the unit region PU is arranged in the display region DA, and a light-emitting layer EML is not arranged in the non-display region NDA. The non-display region NDA may be around (e.g., surround) the display region DA. In one or more embodiments of the disclosure, the non-display region NDA may not be provided or may be arranged only on one side of the display region DA. In one or more embodiments, FIG. 3 illustrates an example shape of the display region DA and the non-display region NDA defined in the display device DD, and the display region DA and the non-display region NDA may be defined to correspond to the display panel DP included in the display device DD.

The unit region PU may be provided in plurality within the display region DA. The unit regions PU may be arranged along the first direction DR1 and the second direction DR2. The unit regions PU may include light-emitting regions for providing information to a user by the display panel DP, a transmission region for increasing the transparency of the display panel DP so that an object PD arranged on the rear surface D-B of the display panel DP can be transmitted (e.g., visible) to the user, and a line region in which signal lines connected to the pixels are arranged.

The gate driving circuit GDC may be arranged in the non-display region NDA. The gate driving circuit GDC may be integrated into the display panel DP through an oxide silicon gate driver circuit (OSG) process or an amorphous silicon gate driver circuit (ASG) process.

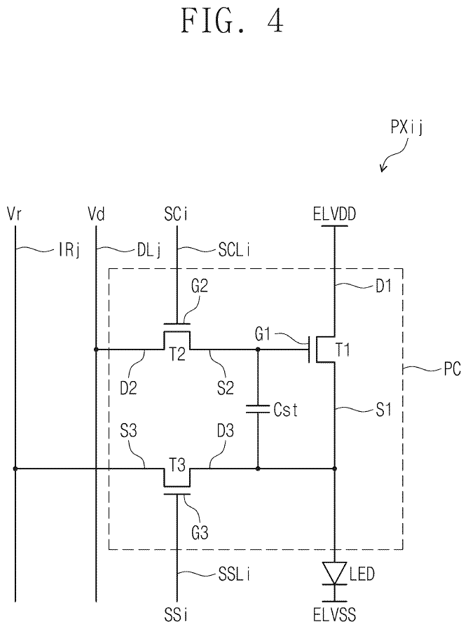

FIG. 4 is an equivalent circuit diagram of a pixel according to one or more embodiments of the disclosure.

FIG. 4 illustrates an example circuit diagram of one pixel PXij among the pixels arranged in the unit region PU (see FIG. 3).

Referring to FIG. 4, the pixel PXij may include a pixel circuit PC and a light-emitting element LED. The pixel circuit PC may include a plurality of transistors T1 to T3 and a capacitor Cst.

The plurality of transistors T1 to T3 may be formed through a low temperature polycrystalline silicon (LTPS) process or a low temperature polycrystalline oxide (LTPO) process. Each of the first to third transistors T1 to T3 may include any one selected from a silicon semiconductor and an oxide semiconductor. In this case, the oxide semiconductor may include a crystalline or amorphous oxide semiconductor, and the silicon semiconductor may include amorphous silicon, polycrystalline silicon, and/or the like, and the disclosure is not limited to any one or more embodiments.

Hereinafter, the first to third transistors T1 to T3 are described as an N-type (kind), but one or more embodiments of the disclosure are not limited thereto, and each of the first to third transistors T1 to T3 may be a P-type (kind) transistor or an N-type (kind) transistor depending on an applied signal. In this case, the source (e.g., source region) and drain (e.g., drain region) of the P-type (kind) transistor may respectively correspond to the drain (e.g., drain region) and source (e.g., source region) of the N-type (kind) transistor.

FIG. 4 illustrates, as an example, a pixel PXij which is connected to an i-th scan line SCLi, an i-th sensing line SSLi, a j-th data line DLj, and a j-th reference line IRj.

The pixel PXij illustrated in FIG. 4 may correspond to any one of the pixels included in the unit pixel PU (see FIG. 3). The pixel circuit PC may include a first transistor T1 (driving transistor), a second transistor T2 (switch transistor), a third transistor T3 (sensing transistor), and a capacitor Cst. However, the pixel circuit PC may further include an additional transistor and an additional capacitor, and the disclosure is not limited to any one or more embodiments.

Each of the first to third transistors T1 to T3 may include a source S1, S2, or S3, a drain D1, D2, or D3, and a gate G1, G2, or G3.

The light-emitting element LED may be an organic light-emitting element or an inorganic light-emitting element including an anode (first electrode) and a cathode (second electrode). Through the first transistor T1, the anode of the light-emitting element LED may receive a first voltage ELVDD and the cathode of the light-emitting element LED may receive a second voltage ELVSS. The light-emitting element LED may be to emit light by receiving the first voltage ELVDD and the second voltage ELVSS.

The first transistor T1 may include a drain D1 that receives the first voltage ELVDD, a source S1 connected to the anode of the light-emitting element LED, and a gate G1 connected to the capacitor Cst. The first transistor T1 may control a driving current that flows through the light-emitting element LED from the first voltage ELVDD in response to a voltage value stored in the capacitor Cst.

The second transistor T2 may include a drain D2 connected to the j-th data line DLj, a source S2 connected to the capacitor Cst, and a gate G2 that receives an i-th write scan signal SCi. The second transistor T2 provides a data voltage Vd to the first transistor T1 in response to the i-th first scan signal SCi.

The third transistor T3 may include a source S3 connected to the j-th reference line IRj, a drain D3 connected to the anode of the light-emitting element LED, and a gate G3 that receives an i-th sampling scan signal SSi. The j-th reference line IRj may receive a reference voltage Vr.

The capacitor Cst may store voltage differences of one or more suitable values according to input signals. For example, the capacitor Cst may store a voltage corresponding to the difference between a voltage received from the second transistor T2 and the first voltage ELVDD.

In this disclosure, the equivalent circuit of the pixel PXij is not limited to the equivalent circuit illustrated in FIG. 4. In one or more embodiments of the disclosure, the pixel PXij may be implemented in one or more suitable forms so that the light-emitting element LED can emit light.

FIG. 5A is an enlarged plan view of a portion of a display region of the display device according to one or more embodiments of the disclosure. FIG. 5A illustrates a planar arrangement of some of the unit regions PU illustrated in FIG. 3.

Among the unit regions PU of FIG. 3, FIG. 5A illustrates three columns of unit regions arranged along the first direction DR1 and three rows of unit regions arranged along the second direction DR2.

Referring to FIGS. 3 and 5A together, the unit regions PU include a first unit region PU-1 and a second unit region PU-2. The second unit region PU-2 is spaced and/or apart (e.g., spaced apart or separated) from the first unit region PU-1 along the second direction DR2. The second unit region PU-2 is parallel to the first unit region PU-1 in the second direction DR2 and may be a unit region that is the closest to the first unit region PU-1 in the second direction DR2.

The first unit region PU-1 includes first pixel regions PXA1-1, PXA1-2, and PXA1-3 arranged to be spaced and/or apart (e.g., spaced apart or separated) from each other along the second direction DR2 and a first transmission region TA1 spaced and/or apart (e.g., spaced apart or separated) from the first pixel regions PXA1-1, PXA1-2, and PXA1-3 along the first direction DR1. The second unit region PU-2 includes second pixel regions PXA2-1, PXA2-2, and PXA2-3 arranged to be spaced and/or apart (e.g., spaced apart or separated) from each other along the second direction DR2 and a second transmission region TA2 spaced and/or apart (e.g., spaced apart or separated) from the second pixel regions PXA2-1, PXA2-2, PXA2-3 along the first direction DR1.

The first pixel regions PXA1-1, PXA1-2, and PXA1-3 may include a plurality of sub-pixel regions. The first pixel regions PXA1-1, PXA1-2, and PXA1-3 may include a (1-1)-th sub-pixel region PXA1-1, a (1-2)-th sub-pixel region PXA1-2, and a (1-3)-th sub-pixel region PXA1-3, which are sequentially arranged along the second direction DR2. Each of the (1-1)-th sub-pixel region PXA1-1, the (1-2)-th sub-pixel region PXA1-2, and the (1-3)-th sub-pixel region PXA1-3 may overlap the first transmission region TA1 in the first direction DR1.

The second pixel regions PXA2-1, PXA2-2, and PXA2-3 may include a plurality of sub-pixel regions. The second pixel regions PXA2-1, PXA2-2, and PXA2-3 may include a (2-1)-th sub-pixel region PXA2-1, a (2-2)-th sub-pixel region PXA2-2, and a (2-3)-th sub-pixel region PXA2-3, which are sequentially arranged along the second direction DR2. Each of the (2-1)-th sub-pixel region PXA2-1, the (2-2)-th sub-pixel region PXA2-2, and the (2-3)-th sub-pixel region PXA2-3 may overlap the second transmission region TA2 in the first direction DR1.

In one or more embodiments, a non-pixel region NPXA may be around (e.g., surround) each of the pixel regions PXA and the transmission region TA adjacent to the pixel regions PXA, which are included in each unit region PU.

According to this disclosure, the wavelengths of the source light provided from each of the plurality of sub-pixel regions included in the pixel regions PXA may be different from each other. For example, the above-described first sub-pixel regions PXA1-1 and PXA2-1 may provide red light, the above-described second sub-pixel regions PXA1-2 and PXA2-2 may provide green light, and the above-described third sub-pixel regions PXA1-3 and PXA2-3 may provide blue light.

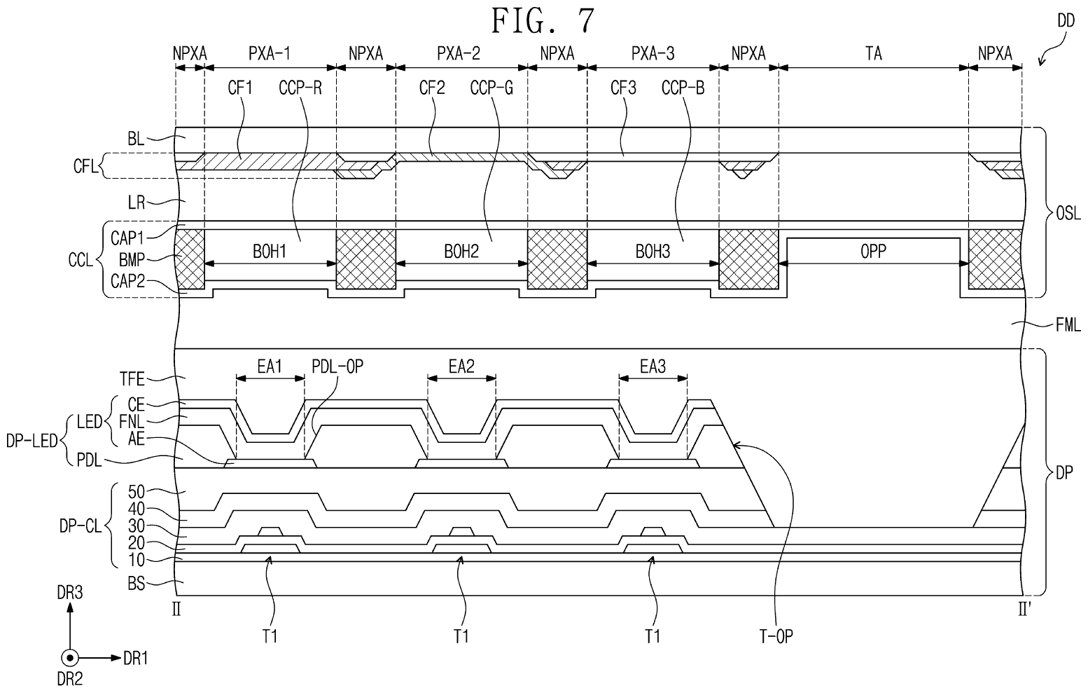

Each of the pixel regions PXA may be defined by a light-emitting opening PDL-OP (see FIG. 6) provided in the pixel defining film PDL (see FIG. 6), and the transmission regions TA may be defined by a transmission opening T-OP (see FIG. 7) provided in the pixel defining film PDL (see FIG. 7).

In the display region DA of the display device according to one or more embodiments of the disclosure, the area of each of the transmission regions TA is larger than the area of each of the pixel regions PXA. In one unit region PU, the area (e.g., planar area) of the transmission region TA is larger than the sum of the planar areas of the pixel regions PXA. In one or more embodiments of the disclosure, the planar area of the first transmission region TA1 included in the first unit region PU-1 may be larger than the sum of the planar areas of the sub-pixel regions PXA1-1, PXA1-2, and PXA1-3. The planar area of the second transmission region TA2 included in the second unit region PU-2 may be larger than the sum of the planar areas of the sub-pixel regions PXA2-1, PXA2-2, and PXA2-3 included in the second unit region PU-2. In one unit region PU, with respect to the total area of the transmission region TA and the pixel regions PXA, the planar area of the transmission region TA may be 60% or more. In the first unit region PU-1, with respect to the total area of the first transmission region TA1 and the sub-pixel regions PXA1-1, PXA1-2, and PXA1-3, the planar area of the first transmission region TA1 may be 60% or more. In the second unit region PU-2, with respect to the total area of the second transmission region TA2 and the sub-pixel regions PXA2-1, PXA2-2, and PXA2-3, the planar area of the second transmission region TA2 may be 60% or more. As the display device according to one or more embodiments of the disclosure includes a transmission region that is larger than the light-emitting regions, the transmittance of the display device is increased and the display device may be used as a transparent display device.

The unit regions PU may further include a third unit region PU-3 to a sixth unit region PU-6. The third unit region PU-3 may be spaced and/or apart (e.g., spaced apart or separated) from the first unit region PU-1 along the first direction DR1. The third unit region PU-3 may be parallel to the first unit region PU-1 in the first direction DR1 and may be a unit region that is the closest to the first unit region PU-1 in the first direction DR1. The fourth unit region PU-4 may be spaced and/or apart (e.g., spaced apart or separated) from the third unit region PU-3 along the second direction DR2. The fourth unit region PU-4 may be parallel to the third unit region PU-3 in the second direction DR2 and may be a unit region that is the closest to the third unit region PU-3 in the second direction DR2. The fifth unit region PU-5 may be spaced and/or apart (e.g., spaced apart or separated) from the third unit region PU-3 along the second direction DR2. The fifth unit region PU-5 may be parallel to the third unit region PU-3 in the second direction DR2 and may be a unit region that is the closest to the third unit region PU-3 in the second direction DR2. The sixth unit region PU-6 may be spaced and/or apart (e.g., spaced apart or separated) from the fourth unit region PU-4 along the second direction DR2. The sixth unit region PU-6 may be parallel to the fourth unit region PU-4 in the second direction DR2 and may be a unit region that is the closest to the fourth unit region PU-4 in the second direction DR2.

The third unit region PU-3 includes third pixel regions PXA3-1, PXA3-2, and PXA3-3 arranged to be spaced and/or apart (e.g., spaced apart or separated) from each other along the second direction DR2 and a third transmission region TA3 spaced and/or apart (e.g., spaced apart or separated) from the third pixel regions PXA3-1, PXA3-2, and PXA3-3 along the first direction DR1. The fourth unit region PU-4 includes fourth pixel regions PXA4-1, PXA4-2, and PXA4-3 arranged to be spaced and/or apart (e.g., spaced apart or separated) from each other along the second direction DR2 and a fourth transmission region TA4 spaced and/or apart (e.g., spaced apart or separated) from the fourth pixel regions PXA4-1, PXA4-2, and PXA4-3 along the first direction DR1. The fifth unit region PU-5 includes fifth pixel regions PXA5-1, PXA5-2, and PXA5-3 arranged to be spaced and/or apart (e.g., spaced apart or separated) from each other along the second direction DR2 and a fifth transmission region TA5 spaced and/or apart (e.g., spaced apart or separated) from the fifth pixel regions PXA5-1, PXA5-2, and PXA5-3 along the first direction DR1. The sixth unit region PU-6 includes sixth pixel regions PXA6-1, PXA6-2, and PXA6-3 arranged to be spaced and/or apart (e.g., spaced apart or separated) from each other along the second direction DR2 and a sixth transmission region TA6 spaced and/or apart (e.g., spaced apart or separated) from the sixth pixel regions PXA6-1, PXA6-2, and PXA6-3 along the first direction DR1.

As described above, in each unit region PU, the area (e.g., planar area) of the transmission region TA is larger than the sum of the planar areas of the pixel regions PXA. In one or more embodiments of the disclosure, the planar area of the third transmission region TA3 included in the third unit region PU-3 may be larger than the sum of the planar areas of the sub-pixel regions PXA3-1, PXA3-2, and PXA3-3 included in the third unit region PU-3. The planar area of the fourth transmission region TA4 included in the fourth unit region PU-4 may be larger than the sum of the planar areas of the sub-pixel regions PXA4-1, PXA4-2, and PXA4-3 included in the fourth unit region PU-4. The planar area of the fifth transmission region TA5 included in the fifth unit region PU-5 may be larger than the sum of the planar areas of the sub-pixel regions PXA5-1, PXA5-2, and PXA5-3 included in the fifth unit region PU-5. The planar area of the sixth transmission region TA6 included in the sixth unit region PU-6 may be larger than the sum of the planar areas of the sub-pixel regions PXA6-1, PXA6-2, and PXA6-3 included in the sixth unit region PU-6.

In the display region DA according to one or more embodiments of the disclosure, a middle region MA is defined in a portion between adjacent unit regions PU along the second direction DR2. A first middle region MA1 is defined between the first unit region PU-1 and the second unit region PU-2. A second middle region MA2 may be defined between the third unit region PU-3 and the fourth unit region PU-4. A third middle region MA3 may be defined between the second unit region PU-2 and the fifth unit region PU-5. A fourth middle region MA4 may be defined between the fourth unit region PU-4 and the sixth unit region PU-6.

A blocking pattern BP (see FIG. 5B), which will be described in more detail later, is arranged in at least a portion of the middle region MA. The blocking pattern BP (see FIG. 5B) may overlap at least a portion of the middle region MA on a plane (e.g., in a plan view of the display device).

FIG. 5B is an enlarged plan view of some components of the display device according to one or more embodiments of the disclosure. FIG. 5B illustrates a planar arrangement shape of the blocking pattern BP and a bank BMP arranged to correspond to a portion of the display region illustrated in FIG. 5A.

Referring to FIGS. 5A and 5B together, a plurality of bank openings BOH corresponding to the pixel regions PXA are provided in the bank BMP. The bank opening BOH may include a first bank opening BOH1 corresponding to the first sub-pixel regions PXA1-1 and PXA2-1, a second bank opening BOH2 corresponding to the second sub-pixel regions PXA1-2 and PXA2-2, and a third bank opening BOH3 corresponding to the third sub-pixel regions PXA1-3 and PXA2-3. Light control patterns CCP-R, CCP-G, and CCP-B (see FIG. 7), which will be described in more detail later, may be arranged within the bank opening BOH.

Open portions OPP corresponding to transmission regions TA may be defined in the bank BMP. The open portion OPP and the bank opening BOH may be regions from which the bank BMP is removed and which the bank BMP does not overlap on a plane (e.g., in a plan view). The open portion OPP may extend in the second direction DR2. For example, the open portion OPP may be provided so as to correspond to both (e.g., simultaneously) the plurality of transmission regions TA arranged along the second direction DR2 and the middle regions MA arranged between them.

The blocking pattern BP is arranged at least in the above-described middle region MA. The blocking pattern BP may overlap at least the middle region MA on a plane (e.g., in a plan view). The blocking pattern BP may include a first blocking pattern BP1 arranged in the first middle region MA1. The blocking pattern BP may include a second blocking pattern BP2 arranged in the second middle region MA2, a third blocking pattern BP3 arranged in the third middle region MA3, and a fourth blocking pattern BP4 arranged in the fourth middle region MA4.

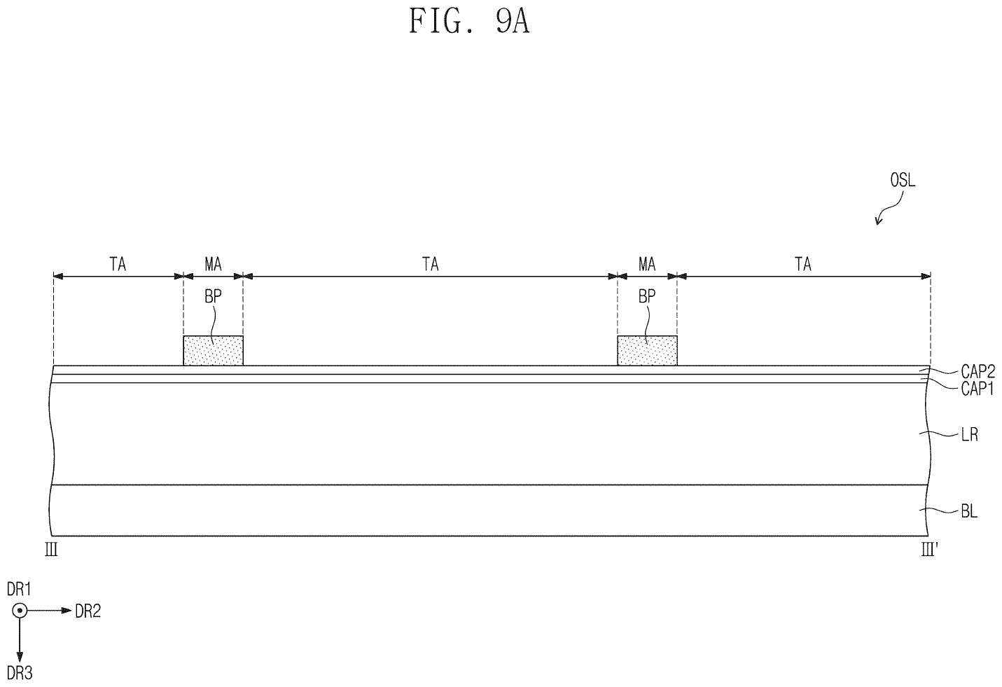

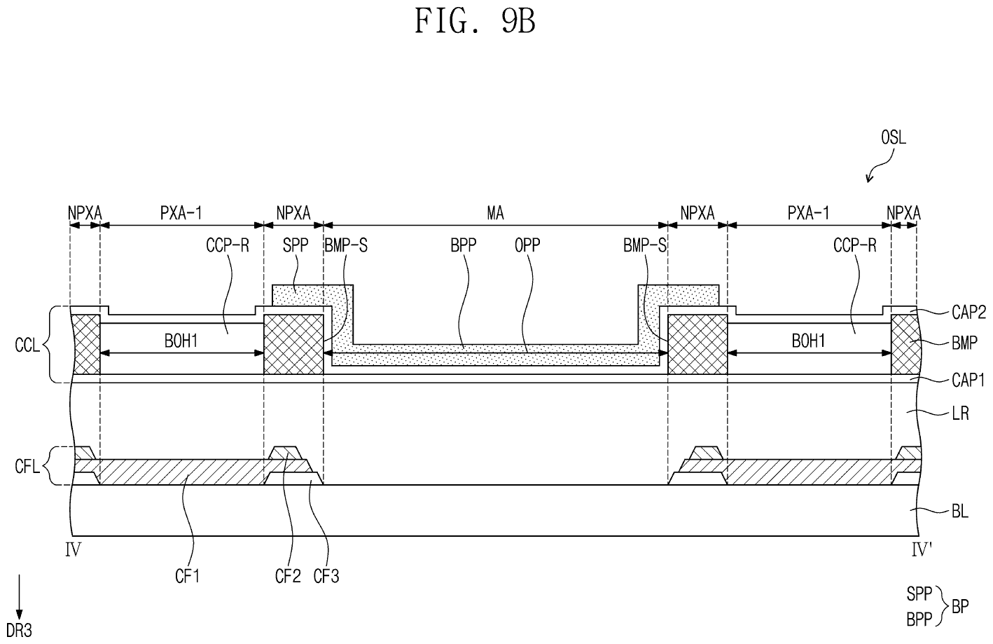

A portion of the blocking pattern BP may overlap the bank BMP on a plane (e.g., in a plan view). The remaining portion of the blocking pattern BP may overlap the open portion OPP on a plane (e.g., in a plan view). The portion of the blocking pattern BP overlapping the bank BMP on a plane (e.g., in a plan view) may be a spacer portion SPP (see FIG. 9B). The remaining portion of the blocking pattern BP overlapping the open portion OPP on a plane (e.g., in a plan view) may be a blocking portion BPP (see FIG. 9B). The specific configuration of the blocking pattern BP will be described in more detail later in the description of FIGS. 9A and 9B.

FIGS. 6 and 7 are cross-sectional views of the display device DD according to one or more embodiments of the disclosure. FIG. 6 is a cross-sectional view taken along the line I-I′ of FIG. 5A. FIG. 7 is a cross-sectional view taken along the line II-II′ of FIG. 5A. In FIGS. 6 and 7, only a portion of the configuration of the display device DD is illustrated, and components such as the window WD (see FIG. 2) are omitted.

Referring to FIG. 6, the display device DD includes a display panel DP and an optical layer OSL arranged on the display panel DP.

The display panel DP may include a base substrate BS, a circuit element layer DP-CL arranged on the base substrate BS, a display element layer DP-LED, and an encapsulation layer TFE.

The base substrate BS may include a synthetic resin film (or layer). The synthetic resin layer may include a thermosetting resin. In one or more embodiments, the synthetic resin layer may include at least one (e.g., at least any one) selected from among an acrylic-based resin, a methacrylic-based resin, polyisoprene, a vinyl-based resin, an epoxy-based resin, a urethane-based resin, a cellulose-based resin, a siloxane-based resin, a polyamide-based resin, and a perylene-based resin. In addition, the base substrate BS may include a glass substrate, a metal substrate, an organic/inorganic composite material substrate, and/or the like.

The circuit element layer DP-CL includes an insulating layer, a semiconductor layer, and a conductive layer formed through processes such as coating and deposition. Hereafter, the insulating layer, the semiconductor layer, and the conductive layer may be selectively patterned through photolithography and etching processes. Through these processes, a semiconductor pattern, a conductive pattern, a signal line, and/or the like are formed. Patterns arranged on a same layer are formed through a same process.

The circuit element layer DP-CL includes a signal line or a driving circuit which constitutes a pixel. The display element layer DP-LED may include a pixel defining film PDL and a light-emitting element LED included in the pixel.

The circuit element layer DP-CL may include first to fifth insulating layers 10, 20, 30, 40, and 50 and conductive patterns. According to one or more embodiments of the disclosure, the first to fourth insulating layers 10 to 40 may be a single inorganic layer or a plurality of inorganic layers, and the fifth insulating layer 50 may be an organic layer.

A light blocking pattern BML may be arranged on the base substrate BS. According to one or more embodiments of the disclosure, the light blocking pattern BML may be connected to the semiconductor pattern of the overlapping transistor T1 and receive a signal applied to the semiconductor pattern to form a sync structure below the semiconductor pattern. According to one or more embodiments of the disclosure, the light blocking pattern BML may include sequentially stacked metal layers. The first layer thereof may include titanium and the second layer thereof may include copper.

The first insulating layer 10 may be arranged on the base substrate BS and

cover the light blocking pattern BML. According to one or more embodiments of the disclosure, the first insulating layer 10 may include sequentially stacked inorganic layers. The first layer thereof may include silicon nitride, and the second layer thereof may include silicon oxide.

The semiconductor pattern of the transistor T1 may be arranged on the first insulating layer 10. The semiconductor pattern may include a source region S1, a channel region A1 (or active region), and a drain region D1. According to one or more embodiments of the disclosure, the semiconductor pattern may include indium gallium zinc oxide (IGZO).

The second insulating layer 20 may be arranged between the semiconductor pattern and the gate G1. The second insulating layer 20 may expose a region except the active region A1 of the semiconductor pattern. The second insulating layer 20 may be patterned by using the gate G1 as a mask. According to one or more embodiments of the disclosure, the second insulating layer 20 may include silicon oxide.

The gate G1 may be arranged on the second insulating layer 20. According to one or more embodiments of the disclosure, the gate G1 may include sequentially stacked metal layers. The first layer thereof may include titanium and the second layer thereof may include copper.

The third insulating layer 30 may be arranged above the first insulating layer 10 and the second insulating layer 20 and cover the gate G1 and the semiconductor pattern exposed from the gate G1. According to one or more embodiments of the disclosure, the third insulating layer 30 may include silicon oxynitride.

A first connection electrode CNE1 may be arranged on the third insulating layer 30. The first connection electrode CNE1 may be connected to the source region S1 through a contact hole defined in the third insulating layer 30. According to one or more embodiments of the disclosure, the first connection electrode CNE1 may include sequentially stacked metal layers. The first layer thereof may include titanium, the second layer thereof may include copper, and the third layer thereof may include indium tin oxide (ITO).

The fourth insulating layer 40 may be arranged on the third insulating layer 30 and cover the first connection electrode CNE1. According to one or more embodiments of the disclosure, the fourth insulating layer 40 may include silicon 1 nitride. As the layer containing silicon nitride has a higher film density than a layer containing silicon oxide and/or silicon oxynitride, the transmittance thereof is reduced. Therefore, in order to increase the transmittance of a transparent display panel DP as in this disclosure, it is desired or required to remove silicon nitride from the transmission region TA.

A second connection electrode CNE2 may be arranged on the fourth insulating layer 40. The second connection electrode CNE2 may be connected to the first connection electrode CNE1 through a contact hole defined in the fourth insulating layer 40. According to one or more embodiments of the disclosure, the second connection electrode CNE2 may include the same material as the first connection electrode CNE1. In the display panel DP according to one or more embodiments of the disclosure, the second connection electrode CNE2 may not be provided, and the disclosure is not limited to any one or more embodiments.

The fifth insulating layer 50 may be arranged on the fourth insulating layer 40

and cover the second connection electrode CNE2. According to one or more embodiments of the disclosure, the fifth insulating layer 50 may include an organic material. For example, the fifth insulating layer 50 may include photosensitive polyimide (PSPI).

The display element layer DP-LED may be arranged on the fifth insulating layer 50. The display element layer DP-LED may include a light-emitting element LED and a pixel defining film PDL. The light-emitting element LED may include a first electrode AE, a functional layer FNL, and a second electrode CE. The functional layer FNL of the light-emitting element LED according to one or more embodiments of the disclosure may include at least one light-emitting layer.

The pixel defining film PDL may be arranged on the fifth insulating layer 50 and cover the second connection electrode CNE2. The pixel defining film PDL may include an organic material. For example, the pixel defining film PDL may include photosensitive polyimide (PSPI). The pixel defining film PDL may include a light-emitting opening PDL-OP. The light-emitting opening PDL-OP of the pixel defining film PDL may be provided in plurality, and the light-emitting openings PDL-OP may be respectively defined as the light-emitting regions described in FIG. 3B. The region in which the pixel defining film PDL is arranged may be defined as a non-light-emitting region.

The first electrode AE of the light-emitting element LED is arranged on the fifth insulating layer 50. The light-emitting opening PDL-OP of the pixel defining film PDL exposes at least a portion of the first electrode AE. According to one or more embodiments of the disclosure, the first electrode AE may include sequentially stacked conductive material layers. For example, the first electrode AE may include a conductive material layer having a three-layer structure. The first layer of the first electrode AE may include indium tin oxide (ITO), the second layer thereof may include silver (Ag), and the third layer thereof may include indium tin oxide (ITO).

The functional layer FNL may include at least one organic material layer. The functional layer FNL may include at least one light-emitting layer. The light-emitting layer may generate light of a specific wavelength. The light-emitting layer may include an organic light-emitting material or an inorganic light-emitting material.

The functional layer FNL may further include a hole control layer and an electron control layer. At least one organic material layer included in the functional layer FNL may be commonly arranged in the light-emitting region and the non-light-emitting region. At least one organic material layer included in the functional layer FNL may be commonly arranged in the pixels. In this specification, layers formed as a common layer may be entirely arranged in the display region DA (see FIG. 3) and the non-display region NDA (see FIG. 3). For example, layers formed as a common layer may be arranged in both the entire display region DA and the entire non-display region NDA. Layers formed as a common layer may be defined as a “common layer”.

The encapsulation layer TFE may be arranged on the display element layer DP-LED and protect the light-emitting element LED. The encapsulation layer TFE may include inorganic encapsulation films T-IOL1 and T-IOL2 and an organic encapsulation film T-OL arranged between the inorganic encapsulation films T-IOL1 and T-IOL2. The inorganic encapsulation films T-IOL1 and T-IOL2 may protect the light-emitting element LED from moisture and oxygen, and the organic encapsulation film T-OL may protect the light-emitting element LED from foreign substances such as dust particles.

The inorganic encapsulation films T-IOL1 and T-IOL2 may prevent or reduce external moisture and/or oxygen from penetrating into the functional layer FNL of the light-emitting element LED. The inorganic encapsulation films T-IOL1 and T-IOL2 may include silicon nitride, silicon oxide, and/or a (e.g., any suitable) combination thereof.

The inorganic encapsulation films T-IOL1 and T-IOL2 may be formed through a deposition process. The inorganic encapsulation films T-IOL1 and T-IOL2 may include a first inorganic encapsulation film T-IOL1 arranged below the organic encapsulation film T-OL and a second inorganic encapsulation film T-IOL2 arranged on the organic encapsulation film T-OL.

The organic encapsulation film T-OL may provide a flat surface on the inorganic encapsulation film. As curves (or unevenness) formed on the upper surface of the first inorganic encapsulation film T-IOL1 and/or particles present on the inorganic layer are covered by the organic encapsulation film T-OL, it is possible to block or reduce the influence of the surface condition of the upper surface of the first inorganic encapsulation film T-IOL1 on components formed on the organic encapsulation film T-OL. The organic encapsulation film T-OL may include an organic material.

The optical layer OSL may convert the color of light provided from a display element. The optical layer OSL may include a light control pattern and a structure to increase light conversion efficiency.

The optical layer OSL may be arranged on the display panel DP. The optical layer OSL may include a light control layer CCL, a low refractive layer LR, a color filter layer CFL, and a base layer BL. In this specification, the optical layer OSL may be referred to as an upper panel.

The light control layer CCL may be arranged on the display element layer DP-LED including the light-emitting element LED. The light control layer CCL may include a bank BMP, a first light control pattern CCP-R, and a first barrier layer CAP1.

The bank BMP may include a base resin and an additive. The base resin may be composed of one or more suitable resin compositions which may be generally referred to as a binder. The additive may include a coupling agent and/or a photoinitiator. The additive may further include a dispersant.

The bank BMP may include a black coloring agent to block light. The bank BMP may include a black dye and/or a black pigment mixed in the base resin. In one or more embodiments of the disclosure, the black coloring agent may include carbon black, or may include a metal such as chromium or an oxide thereof.

The bank BMP may include a first bank opening BOH1 corresponding to the light-emitting opening PDL-OP. On a plane (e.g., in a plan view), the first bank opening BOH1 may overlap the light-emitting opening PDL-OP and have a larger area than the light-emitting opening PDL-OP. For example, the first bank opening BOH1 may have a larger area than a first light-emitting region EA1 defined by the light-emitting opening PDL-OP. In one or more embodiments, in this specification, the expression “one element corresponds to another element” refers to that two elements overlap each other if (e.g., when) viewed in the thickness direction DR3 of the display panel DP and is not limited to having a same area.

The first light control pattern CCP-R may be arranged inside the first bank opening BOH1. The first light control pattern CCP-R may change the optical properties of the source light.

The first light control pattern CCP-R may include a quantum dot to change the optical properties of the source light. The first light control pattern CCP-R may include a first quantum dot that converts the source light into light of a different wavelength. In the first light control pattern CCP-R overlapping the first sub-pixel region PXA-1, the first quantum dot may convert the source light into red light.

In this specification, a “quantum dot” refers to a crystal of a semiconductor compound. The quantum dot may be to emit light of one or more suitable light-emitting wavelengths depending on the size of the crystal. The quantum dot may be to emit light of one or more suitable light-emitting wavelengths by adjusting the element ratio of the quantum dot compound.

The diameter of the quantum dot may be, for example, about 1 nm to about 10 nm. In the present disclosure, when quantum dot, quantum dots, or quantum dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The quantum dot may be synthesized by a wet chemical process, a metal organic chemical vapor deposition process, a molecular beam epitaxy process, or a suitable process similar thereto.

The wet chemical process is a method of mixing an organic solvent and a precursor material with each other and then growing a quantum dot particle crystal.

When the crystal grows, the organic solvent may naturally act (e.g., serve) as a dispersant coordinated on the surface of the quantum dot crystal and control the growth of the crystal. Therefore, the wet chemical process may be easier than a vapor deposition method such as a metal organic chemical vapor deposition (MOCVD) process and/or a molecular beam epitaxy (MBE) process, and it is possible to control the growth of quantum dot particles through a low-cost process.

The quantum dot may have a single structure in which the concentration of each element included in the quantum dot is uniform or a core-shell double-layer structure. The quantum dot or the core of the quantum dot may be selected from among a group II-VI compound, a group III-V compound, a group III-VI compound, a group I-III-VI compound, a group IV-VI compound, a group IV element, a group IV compound, and/or one or more (e.g., any suitable) combinations thereof.

The group II-VI compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof. In one or more embodiments, the group II-VI semiconductor compound may further include a group I metal and/or a group IV element. A group I-II-VI compound may be selected from among CuSnS and CuZnS, and a Group II-IV-VI compound may be selected from among ZnSnS and/or the like. A group I-II-IV-VI compound may be selected from among quaternary compounds selected from the group consisting of Cu₂ZnSnS₂, Cu₂ZnSnS₄, Cu₂ZnSnSe₄, Ag₂ZnSnS₂, and mixtures thereof.

The group III-VI compound may include a binary compound such as In₂S₃ and/or In₂Se₃, a ternary compound such as InGaS₃ and/or InGaSe₃, or any combinations thereof.

The group I-III-VI compound may be selected from among a ternary compound selected from the group consisting of AgInS, AgInS₂, CuInS, CuInS₂, AgGaS₂, CuGaS₂ CuGaO₂, AgGaO₂, AgAlO₂, and mixtures thereof, and a quaternary compound such as AgInGaS₂, and CuInGaS₂.

The group III-V compound may be selected from the group consisting of: a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In one or more embodiments, the group III-V compound may further include a group Il metal. For example, InZnP and/or the like may be selected as a group III-II-V compound.

The group IV-VI compound may be selected from the group consisting of: a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof.

An example of a group II-IV-V semiconductor compound may be a ternary compound selected from the group consisting of ZnSnP, ZnSnP₂, ZnSnAs₂, ZnGeP₂, ZnGeAs₂, CdSnP₂, CdGeP₂, and mixtures thereof.

The group IV element may be selected from the group consisting of Si, Ge, and mixtures thereof. The group IV compound may be a binary compound selected from the group consisting of SiC, SiGe, and mixtures thereof.

Each element included in multi-element compounds, such as the binary compounds, the ternary compounds, and the quaternary compounds, may be present in a particle at a substantially uniform or non-uniform concentration. For example, the above chemical formulas may refer to types (kinds) of elements included in the compounds, and the ratios of elements in the compounds may be different from each other. For example, AgInGaS₂ may refer to AgInₓGa₁₋ₓS₂ (x is a real number between 0 and 1).

In this case, the binary compounds, the ternary compounds, or the quaternary compounds may be present in a particle at a substantially uniform concentration, or they may be present in the same particle by being divided into states or regions in which the concentration distributions thereof are partially different from one another. In addition, the quantum dots may have a core/shell structure in which one quantum dot surrounds another quantum dot. The core/shell structure may have a concentration gradient in which the concentration of an element present in the shell gradually decreases toward the core.

In one or more embodiments of the disclosure, the quantum dots may have a core-shell structure including: a core including a nanocrystal described above; and a shell around (e.g., surrounding) the core. The shell of the quantum dots may serve as a protective layer for maintaining semiconductor characteristics by preventing or reducing the chemical modification of the core and/or as a charging layer for imparting electrophoretic characteristics to the quantum dots. The shell may be single-layered or multi-layered. An example of the shell of the quantum dots may include a metal or non-metal oxide, a semiconductor compound, and/or a (e.g., any suitable) combination thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄, and/or NiO, or a ternary compound such as MgAl₂O₄, CoFe₂O₄, NiFe₂O₄, and/or CoMn₂O₄, but one or more embodiments of the disclosure are not limited thereto.

In addition, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but one or more embodiments of the disclosure are not limited thereto.

The quantum dot may have a full width of half maximum (FWHM) of a light-emitting wavelength spectrum of about 45 nm or less, about 40 nm or less, or about 30 nm or less, and within those ranges, it is possible to improve color purity and/or color reproducibility. In addition, because light emitted through the quantum dot is emitted in all directions, a wide viewing angle may be improved.

In addition, the shape of the quantum dot is not particularly limited to those generally used in the art, for example, a shape such as a spherical, pyramidal, multi-armed, or cubic nanoparticle, nanotube, nanowire, nanofiber, and nanoplate particle may be used.

Because an energy band gap may be controlled or selected by adjusting the size of the quantum dot or the ratio of elements in a quantum dot compound, it is possible to obtain light of one or more suitable wavelengths from a quantum dot light-emitting layer. Therefore, by using the quantum dot described above (using quantum dots of different sizes or different element ratios in the quantum dot compound), it is possible to implement a light-emitting element configured to emit light of one or more suitable wavelengths. For example, the size of the quantum dot or the ratio of elements in the quantum dot compound may be controlled or selected so as to allow the quantum dot to emit red light, green light, and/or blue light. In addition, the quantum dots may be configured to emit white light by combining light of one or more suitable colors.

In one or more embodiments of the disclosure, the quantum dot included in the first light control pattern CCP-R overlapping the first sub-pixel region PXA-1 may have a red light-emitting color. When the particle size of a quantum dot is smaller, light of a shorter wavelength range may be emitted. For example, among quantum dots having a same core, the quantum dots emitting green color light may have a smaller particle size than the quantum dots emitting red color light. In addition, among quantum dots having a same core, the quantum dots emitting blue color light may have a smaller particle size than the quantum dots emitting green color light. However, one or more embodiments of the disclosure are not limited thereto, and even among quantum dots having a same core, the particle sizes thereof may be adjusted according to a shell-forming material, a shell thickness, and/or the like.

In one or more embodiments, if (e.g., when) the quantum dots have one or more suitable light-emitting colors such as a blue color, a red color, and/or a green color, the quantum dots having different light-emitting colors may respectively have different core materials.

The first light control pattern CCP-R may further include a scatterer. The first light control pattern CCP-R may include a first quantum dot, which converts blue light into red light, and a scatterer which scatters light.

The scatterer may be an inorganic particle. For example, the scatterer may include at least one selected from among TiO₂, ZnO, Al₂O₃, SiO₂, and hollow silica.

The scatterer may include any one selected from among TiO₂, ZnO, Al₂O₃, SiO₂, and hollow silica, or may be a mixture of two or more materials selected from among TiO₂, ZnO, Al₂O₃, SiO₂, and hollow silica.

The first light control pattern CCP-R may include a base resin that disperses the first quantum dots and the scatterers. The base resin is a medium, in which the first quantum dots and the scatterers are dispersed, and may be made of one or more suitable resin compositions which may generally be referred to as a binder. For example, the base resin may be an acrylic-based resin, a urethane-based resin, a silicone-based resin, an epoxy-based resin, and/or the like. The base resin may be a transparent resin.

In this embodiment, the first light control pattern CCP-R may be formed by an inkjet process. A liquid composition may be provided in the first bank opening BOH1. The volume of the composition which is polymerized through a heat curing process or a light curing process is reduced after curing.

The light control layer CCL may include a first barrier layer CAP1 arranged on one surface of the first light control pattern CCP-R. The first barrier layer CAP1 may serve to prevent or reduce the penetration of moisture and/or oxygen (hereinafter referred to as ‘moisture/oxygen’) and improve the optical properties of the optical layer

OSL by adjusting a refractive index. The first barrier layer CAP1 is arranged on one upper or lower surface of the first light control pattern CCP-R so as to be able to block or protect the first light control pattern CCP-R from being exposed to moisture/oxygen, and in one or more embodiments, the quantum dots included in the first light control pattern CCP-R may be blocked or protected from being exposed to moisture/oxygen.

The first barrier layer CAP1 may also protect the first light control pattern CCP-R from an external impact.

In one or more embodiments of the disclosure, the first barrier layer CAP1 may be arranged to be spaced and/or apart (e.g., spaced apart or separated) from the display element layer DP-LED with the first light control pattern CCP-R interposed therebetween. For example, the first barrier layer CAP1 may be arranged on the upper surface of the first light control pattern CCP-R. In one or more embodiments of the disclosure, the light control layer CCL may include a second barrier layer CAP2 arranged between the first light control pattern CCP-R and the display element layer DP-LED. The first barrier layer CAP1 may cover the upper surface of the first light control pattern CCP-R adjacent to the low refractive layer LR, and the second barrier layer CAP2 may cover the lower surface of the first light control pattern CCP-R adjacent to the display element layer DP-LED. In one or more embodiments, the “upper surface” may be a surface located at the top, based on the third direction DR3, and the “lower surface” may be a surface located at the bottom, based on the third direction DR3.

In addition, the first barrier layer CAP1 and the second barrier layer CAP2 may cover one (e.g., a respective one) surface of the bank BMP as well as the first light control pattern CCP-R.

The first barrier layer CAP1 may cover one surface of the bank BMP and the first light control pattern CCP-R adjacent to the low refractive layer LR. The first barrier layer CAP1 may be arranged directly below the low refractive layer LR. The second barrier layer CAP2 may be arranged directly on a filling layer FML. The light control layer CCL may be arranged on the display element layer DP-LED and the encapsulation layer TFE with the second barrier layer CAP2 interposed therebetween.

The first barrier layer CAP1 and the second barrier layer CAP2 may include an inorganic material. In the display panel DP according to one or more embodiments of the disclosure, the first barrier layer CAP1 may include silicon oxynitride (SiON). In one or more embodiments, both the first barrier layer CAP1 and the second barrier layer CAP2 may include silicon oxynitride. Without being limited thereto, however, each of the first barrier layer CAP1 and the second barrier layer CAP2 may include silicon oxide (SiOx) or silicon nitride (SiNx). In one or more embodiments of the disclosure, the first barrier layer CAP1 arranged on the first light control pattern CCP-R may include silicon oxynitride, and the second barrier layer CAP2 arranged the first light control pattern CCP-R may include silicon oxide.

The color filter layer CFL may be arranged on the light control layer CCL. The color filter layer CFL includes at least one color filter. The color filter transmits light of a specific wavelength range and blocks light outside the specific wavelength range.

A first color filter CF1 corresponding to the first sub-pixel region PXA-1 may be to transmit red light and block green light and blue light.

The first color filter CF1 includes a base resin and dye and/or pigment dispersed in the base resin. The base resin is a medium, in which dye and/or pigment are dispersed, and may be made of one or more suitable resin compositions which may be generally referred to as a binder.

The first color filter CF1 may have a substantially uniform thickness in the first sub-pixel region PXA-1. Light converted from blue light, which is the source light, to red light through the first light control pattern CCP-R may be provided to the outside with substantially uniform luminance within the first sub-pixel region PXA-1.

The optical layer OSL may include a low refractive layer LR arranged between the light control layer CCL and the color filter layer CFL. The low refractive layer LR may be arranged directly on the first barrier layer CAP1, and the color filter layer CFL may be arranged directly on the low refractive layer LR. The lower surface of the low refractive layer LR may be in contact with the upper surface of the first barrier layer CAP1, and the upper surface of the low refractive layer LR may be in contact with the lower surfaces of the color filters CF1, CF2, and CF3 of the color filter layer CFL.

The low refractive layer LR may be arranged between the light control layer CCL and the color filter layer CFL to function as an optical functional layer to increase light extraction efficiency or prevent or reduce reflected light from entering the light control layer CCL. The low refractive layer LR may have a lower refractive index than an adjacent layer.

In one or more embodiments of the disclosure, the display panel DP may further include a base layer BL arranged on the color filter layer CFL. The base layer BL may be a member that provides a reference surface on which the color filter layer CFL, the low refractive layer LR, and the light control layer CCL are arranged. The base layer BL may be a glass substrate, a metal substrate, or a plastic substrate. However, one or more embodiments of the disclosure are not limited thereto, and the base layer BL may be an inorganic layer, an organic layer, or a composite material layer. In addition, unlike what is illustrated, in one or more embodiments of the disclosure, the base layer BL may not be provided.

In one or more embodiments, an anti-reflection layer may be arranged on the base layer BL. The anti-reflection layer may reduce the reflectance of external light incident from the outside. The anti-reflection layer may selectively transmit light emitted from the display panel DP. In one or more embodiments of the disclosure, the anti-reflection layer may be a single layer containing dye and/or pigment dispersed in a base resin. The anti-reflection layer may be provided as one substantially continuous layer that completely overlaps all of the pixel regions PXA (see FIG. 3B).

The anti-reflection layer may not include (e.g., may exclude) a polarizing layer. Accordingly, light passing through the anti-reflection layer and incident toward the display element layer DP-LED may not be polarized. The display element layer DP-LED may receive unpolarized light from above the anti-reflection layer.

The display device DD according to one or more embodiments of the disclosure may further include a filling layer FML arranged between the optical layer OSL and the display panel DP. In one or more embodiments of the disclosure, the filling layer FML may fill a space between the optical layer OSL and the display panel DP.

The filling layer FML may function as a buffer between the optical layer OSL and the display panel DP. In one or more embodiments of the disclosure, the filling layer FML may function as a shock absorber and increase the strength of the display panel DP. The filling layer FML may be formed from a filling resin including a polymer resin. For example, the filling layer FML may be formed from a filling layer resin including an acrylic-based resin or an epoxy-based resin.

Referring to FIG. 7, the display panel DP may include a base substrate BS and a circuit element layer DP-CL arranged on the base substrate BS. The circuit element layer DP-CL may be arranged on the base substrate BS. The circuit element layer DP-CL may include an insulating layer, a semiconductor pattern, a conductive pattern, a signal line, and/or the like. An insulating layer, a semiconductor layer, and a conductive layer may be formed on the base substrate BS by processes such as coating and deposition, and then the insulating layer, the semiconductor layer, and the conductive layer may be selectively patterned through multiple photolithography processes. Consequently, the semiconductor pattern, the conductive pattern, and the signal lines included in the circuit element layer DP-CL may be created (formed). In one or more embodiments of the disclosure, the circuit element layer DP-CL may include a transistor T1, a buffer layer, and a plurality of insulating layers.

The light-emitting element LED according to one or more embodiments of the disclosure may include a first electrode AE, a second electrode CE opposite to (e.g., facing) the first electrode AE, and a functional layer FNL between the first electrode AE and the second electrode CE. The functional layer FNL included in the light-emitting element LED may include at least a light-emitting layer. The light-emitting layer may include an organic light-emitting material or a quantum dot. The functional layer FNL may further include a hole control layer and an electron control layer. In one or more embodiments, the light-emitting element LED may further include a capping layer arranged on the second electrode CE.

The pixel defining film PDL may be arranged on the circuit element layer DP-CL and cover a portion of the first electrode AE. A light-emitting opening PDL-OP is defined in the pixel defining film PDL. The light-emitting opening PDL-OP of the pixel defining film PDL exposes at least a portion of the first electrode AE. In this embodiment, light-emitting regions EA1, EA2, and EA3 are defined to correspond to partial regions of the first electrode AE exposed by the light-emitting opening PDL-OP.

The display element layer DP-LED may include a first light-emitting region EA1, a second light-emitting region EA2, and a third light-emitting region EA3. The first light-emitting region EA1, the second light-emitting region EA2, and the third light-emitting region EA3 may be divided by the pixel defining film PDL. The first light-emitting region EA1, the second light-emitting region EA2, and the third light-emitting region EA3 may respectively correspond to the first sub-pixel region PXA-1, the second sub-pixel region PXA-2, and the third sub-pixel region PXA-3.

The light-emitting regions EA1, EA2, and EA3 may overlap the pixel regions PXA-1, PXA-2, and PXA-3. When viewed on a plane (e.g., in a plan view), the areas of the pixel regions PXA-1, PXA-2, and PXA-3 divided by the color filters CF1, CF2, and CF3 may be larger than the areas of the light-emitting regions EA1, EA2, and EA3 divided by the pixel defining film PDL. Without being limited thereto, however, the areas of the pixel regions PXA-1, PXA-2, and PXA-3 may be substantially the same as the areas of the light-emitting regions EA1, EA2, and EA3.

In the light-emitting element LED, the first electrode AE is arranged on the circuit element layer DP-CL. The first electrode AE may be an anode or a cathode. In addition, the first electrode AE may be a pixel electrode. The first electrode AE may be a transmissive electrode, a semi-transmissive electrode, or a reflective electrode.

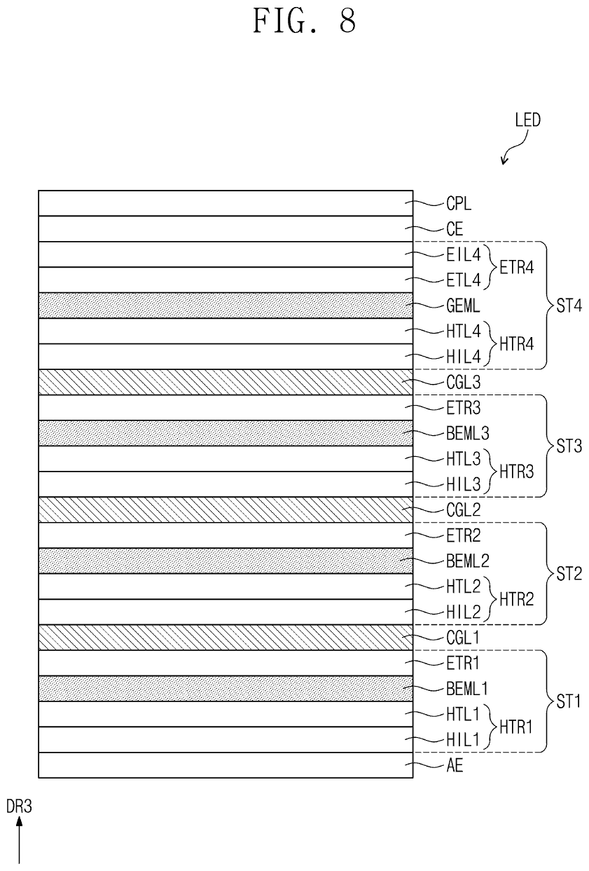

FIG. 8 is a cross-sectional view of a light-emitting element according to one or more embodiments of the disclosure. The configuration of the functional layer FNL in the light-emitting element according to one or more embodiments of the disclosure, which is illustrated in FIGS. 6 and 7, is described in more detail in FIG. 8. FIG. 8 illustrates, as an example, a light-emitting element LED including a plurality of light-emitting stacks ST1, ST2, ST3, and ST4 arranged between the first electrode AE and the second electrode CE.

Referring to FIG. 8, the light-emitting element LED according to one or more embodiments of the disclosure includes a first electrode AE, a second electrode CE opposite to (e.g., facing) the first electrode AE, and first to fourth light-emitting stacks ST1, ST2, ST3, and ST4 arranged between the first electrode AE and the second electrode CE. In one or more embodiments, FIG. 8 illustrates, as an example, that the light-emitting element LED includes four light-emitting stacks, but the number of the light-emitting stacks included in the light-emitting element LED is not limited thereto and may be less or more than four.

The light-emitting element LED may include first to third charge generation layers CGL1, CGL2, and CGL3 arranged between the first to fourth light-emitting stacks ST1, ST2, ST3, and ST4.

When a voltage is applied, each of the first to third charge generation layers CGL1, CGL2, and CGL3 may generate charges (electrons and holes) by forming a complex through an oxidation-reduction reaction. Hereafter, the first to third charge generation layers CGL1, CGL2, and CGL3 may respectively provide the generated charges to the stacks ST1, ST2, ST3, and ST4 adjacent thereto. The first to third charge generation layers CGL1, CGL2, and CGL3 may improve (e.g., double) the efficiency of a current generated in the stacks ST1, ST2, ST3, and ST4 adjacent thereto and play a role in controlling the balance of charges between the stacks ST1, ST2, ST3, and ST4 adjacent thereto.

Each of the first to third charge generation layers CGL1, CGL2, and CGL3 may include an N-type (kind) layer and a P-type (kind) layer. The first to third charge generation layers CGL1, CGL2, and CGL3 may have a structure in which the N-type (kind) layer and the P-type (kind) layer are bonded to each other. Without being limited thereto, however, the first to third charge generation layers CGL1, CGL2, and CGL3 may include only one (e.g., any one) of the N-type (kind) layer or the P-type (kind) layer. The N-type (kind) layer may be a charge generation layer that provides electrons to an adjacent stack. The N-type (kind) layer may be a layer in which an n-dopant is doped in a base material. The P-type (kind) layer may be a charge generation layer that provides holes to an adjacent stack.

In one or more embodiments of the disclosure, the thickness of each of the first to third charge generation layers CGL1, CGL2, and CGL3 may be about 1 Angstrom (Å) to about 150 Angstroms (Å). The concentration of the n-dopant doped in the first to third charge generation layers CGL1, CGL2, and CGL3 may be about 0.1% to about 3%, for example, about 0.1% to about 1%. If (e.g., when) the concentration is less than about 0.1%, the effect of the first to third charge generation layers CGL1, CGL2, and CGL3, which control the balance of charges, may hardly occur. When the concentration is greater than about 3%, the light efficiency of the light-emitting element

LED may be reduced.

Each of the first to third charge generation layers CGL1, CGL2, and CGL3 may include a charge generation compound composed of an arylamine-based organic compound, a metal, a metal oxide, a metal carbide, a metal fluoride, and/or a (e.g., any suitable) mixture thereof. For example, the arylamine-based organic compound may include α-NPD, 2-TNATA, TDATA, MTDATA, sprio-TAD, and/or sprio-NPB. The metal may include cesium (Cs), molybdenum (Mo), vanadium (V), titanium (Ti), tungsten (W), barium (Ba), and/or lithium (Li). The metal oxide, the metal carbide, and the metal fluoride may include Re₂O₇, MoO₃, V₂O₅, WO₃, TiO₂, Cs₂CO₃, BaF, LiF, and/or CsF. However, the materials of the first to third charge generation layers CGL1, CGL2, and CGL3 are not limited to the above examples.

Each of the first to fourth light-emitting stacks ST1, ST2, ST3, and ST4 may include a light-emitting layer. The first light-emitting stack ST1 may include a first light-emitting layer BEML1, the second light-emitting stack ST2 may include a second light-emitting layer BEML2, the third light-emitting stack ST3 may include a third light-emitting layer BEML3, and the fourth light-emitting stack ST4 may include a fourth light-emitting layer GEML. Some of the light-emitting layers included in the first to fourth light-emitting stacks ST1, ST2, ST3, and ST4 may be to emit light of substantially a same color, and some of them may be to emit light of different colors.

In one or more embodiments of the disclosure, the first to third light-emitting layers BEML1, BEML2, and BEML3 of the first to third light-emitting stacks ST1, ST2, and ST3 may be to emit substantially a same first color light. For example, the first color light may be blue light which is the source light described above. The wavelength range of light emitted from the first to third light-emitting layers BEML1, BEML2, and BEML3 may be about 420 nm to about 480 nm.

The fourth light-emitting layer GEML of the fourth light-emitting stack ST4 may be to emit a second color light different from the first color light. For example, the second color light may be green light. The wavelength range of light emitted from the fourth light-emitting layer GEML may be about 520 nm to about 600 nm.

The light-emitting element LED may be to emit light in a direction from the first electrode AE to the second electrode CE. In the light-emitting element LED according to one or more embodiments of the disclosure, the plurality of stacks ST1, ST2, ST3, and ST4 may respectively include hole transport regions HTR1, HTR2, HTR3, and HTR4 (corresponding to HTR, MHRT1, MHTR2 and MHTR3 shown in FIG. 8) and electron transport regions ETR1, ETR2, ETR3, and ETR4 (corresponding to METL1, METL2, METL3 and ETR shown in FIG. 8). The hole transport regions HTR1, HTR2, HTR3, and HTR4 may be to transmit holes, which are provided from the first electrode AE or the charge generation layers CGL1, CGL2, and CGL3, to the light-emitting layer. The electron transport regions ETR1, ETR2, ETR3, and ETR4 may be to transmit electrons, which are provided from the second electrode CE or the charge generation layers CGL1, CGL2, and CGL3, to the light-emitting layer.

It is illustrated as an example that, based on the direction in which light is emitted, the light-emitting element LED according to one or more embodiments of the disclosure has a structure in which the hole transport regions HTR1, HTR2, HTR3, and HTR4 are arranged below the light-emitting layers BEML1, BEML2, BEML3, and GEML included in the plurality of stacks ST1, ST2, ST3, and ST4, and the electron transport regions ETR1, ETR2, ETR3, and ETR4 are arranged on the light-emitting layers BEML1, BEML2, BEML3, and GEML included in the plurality of stacks ST1, ST2, ST3, and ST4. For example, the light-emitting element LED according to one or more embodiments of the disclosure may have a forward element structure. Without being limited thereto, however, based on the direction in which light is emitted, the light-emitting element LED according to one or more embodiments of the disclosure may have an inverted element structure in which the electron transport regions ETR1, ETR2, ETR3, and ETR4 are arranged below the light-emitting layers BEML1, BEML2, BEML3, and GEML included in the plurality of stacks ST1, ST2, ST3, and ST4, and the hole transport regions HTR1, HTR2, HTR3, and HTR4 are arranged on the light-emitting layers BEML1, BEML2, BEML3, and GEML included in the plurality of stacks ST1, ST2, ST3, and ST4.

The hole transport regions HTR1, HTR2, HTR3, and HTR4 may respectively include hole injection layers HIL1, HIL2, HIL3, and HIL4 (corresponding to HIL, MHIL1, MHIL2, and MHIL3 shown in FIG. 8) and hole transport layers HTL1, HTL2, HTL3, and HTL4 (corresponding to HTL, MHTL1, MHTL2, and MHTL3 shown in FIG. 8) arranged on the hole injection layers HIL1, HIL2, HIL3, and HIL4. The hole transport layers HTL1, HTL2, HTL3, and HTL4 may be in contact with the lower surface of the light-emitting layer. Without being limited thereto, however, the hole transport regions HTR1, HTR2, HTR3, and HTR4 may further include a hole-side additional layer arranged on the hole transport layers HTL1, HTL2, HTL3, and HTL4. The hole-side additional layer may include at least one of a hole buffer layer, a light-emitting auxiliary layer, or an electron blocking layer. The hole buffer layer may increase light-emitting efficiency by compensating for a resonance distance depending on the wavelength of light emitted from the light-emitting layer. The electron blocking layer may serve to prevent or reduce electrons from being injected from the electron transport regions to the hole transport regions.

The electron transport regions ETR1, ETR2, ETR3, and ETR4 may include an electron transport layer. The electron transport regions ETR1, ETR2, ETR3, and ETR4 may further include an electron injection layer arranged on the electron transport layer. For example, a fourth electron transport region ETR4 (e.g., ETR shown in FIG. 8) included in the fourth light-emitting stack ST4 may further include a fourth electron injection layer EIL4 (e.g., EIL shown in FIG. 8) arranged on a fourth electron transport layer ETL4. The electron transport regions ETR1, ETR2, ETR3, and ETR4 may further include an electron-side additional layer arranged between the electron transport layer and the light-emitting layer. The electron-side additional layer may include at least one of an electron buffer layer or a hole blocking layer.

In the light-emitting element LED according to one or more embodiments of the disclosure, the first electrode AE may be a reflective electrode. For example, the first electrode AE may include Ag, Mg, Cu, Al, Pt, Pd, Au, Ni, Nd, Ir, Cr, Li, Ca, LiF/Ca, LIF/Al, Mo, Ti, W, In, Zn, Sn, or a compound or mixture thereof (for example, a mixture of Ag and Mg), which exhibits a high reflectance. In one or more embodiments, the first electrode AE may have a multi-layered structure including: a reflective film formed of the above materials; and a transparent conductive film formed of indium tin oxide (ITO), indium zinc oxide (IZO), zinc oxide (ZnO), indium tin zinc oxide (ITZO), and/or the like. For example, the first electrode AE may have a two-layer structure of ITO/Ag or a three-layer structure of ITO/Ag/ITO, but one or more embodiments of the disclosure are not limited thereto. In addition, without being limited thereto, the first electrode AE may include an above-described metal material, a combination of two or more metal materials selected from among the above-described metal materials, an oxide of the above-described metal materials, and/or the like. The thickness of the first electrode AE may be about 70 nm to about 1000 nm. For example, the thickness of the first electrode AE may be about 100 nm to about 300 nm.

In the light-emitting element LED according to one or more embodiments of the disclosure, each of the hole transport regions HTR1, HTR2, HTR3, and HTR4 may have a single-layered structure made of a single material, a single-layered structure made of a plurality of different materials, or a multi-layered structure having a plurality of layers made of a plurality of different materials.

Each of the hole transport regions HTR1, HTR2, HTR3, and HTR4 may be formed by using one or more suitable methods such as a vacuum deposition method, a spin coating method, a casting method, a Langmuir-Blodgett (LB) method, an inkjet printing method, a laser printing method, and/or a laser induced thermal imaging (LITI) method.

Each of the hole transport regions HTR1, HTR2, HTR3, and HTR4 may contain a phthalocyanine compound such as copper phthalocyanine, DNTPD (N1,N1′-([1, 1′-biphenyl]-4,4′-diyl)bis(N1-phenyl-N4, N4-di-m-tolylbenzene-1,4-diamine)), m-MTDATA (4,4′,4″-[tris(3-methylphenyl)phenylamino]triphenylamine), TDATA (4,4′,4″-Tris(N,N-diphenylamino)triphenylamine), 2-TNATA (4,4′,4″-tris[N(2-naphthyl)-N-phenylamino]-triphenylamine), PEDOT/PSS (Poly (3,4-ethylenedioxythiophene)/Poly(4-styrenesulfonate)), PANI/DBSA (Polyaniline/Dodecylbenzene sulfonic acid), PANI/CSA (Polyaniline/Camphor sulfonic acid), PANI/PSS (Polyaniline/Poly(4-styrene sulfonate)), NPB (N,N′-di(naphthalene-l-yl)-N,N′-diphenyl-benzidine), polyether ketone containing triphenylamine (TPAPEK), 4-Isopropyl-4′-methyldiphenyliodonium[Tetrakis(pentafluorophenyl)borate], HATCN (dipyrazino [2,3-f: 2′, 3′-h]quinoxaline-2,3,6,7, 10, 11-hexacarbonitrile), and/or the like.

Each of the hole transport regions HTR1, HTR2, HTR3, and HTR4 may contain a carbazole-based derivative such as N-phenylcarbazole and/or polyvinylcarbazole, a fluorene-based derivative, TPD (N,N′-bis (3-methylphenyl)-N,N′-diphenyl-[1,1′-biphenyl]-4,4′-diamine), a triphenylamine-based derivative such as TCTA (4,4′,4″-tris(N-carbazolyl)triphenylamine), NPB (N,N′-di(naphthalene-1-yl)-N,N′-diplienyl-benzidine), TAPC (4,4′-Cyclohexylidene bis[N,N-bis(4-methylphenyl)benzenamine]), HMTPD (4,4′-Bis[N,N′-(3-tolyl)amino]-3,3′-dimethylbiphenyl), mCP (1,3-Bis(N-carbazolyl)benzene), and/or the like.

In addition, each of the hole transport regions HTR1, HTR2, HTR3, and HTR4 may contain CzSi (9-(4-tert-Butylphenyl)-3,6-bis(triphenylsilyl)-9H-carbazole), CCP (9-phenyl-9H-3,9′-bicarbazole), mDCP (1,3-bis(1,8-dimethyl-9H-carbazol-9-yl)benzene), and/or the like.

The hole transport regions HTR1, HTR2, HTR3, and HTR4 may include the compounds of the hole transport region described above in at least one of the hole injection layers HIL1, HIL2, HIL3, and HIL4, the hole transport layers HTL1, HTL2, HTL3, and HTL4, or the hole-side additional layer.

The thickness of each of the hole transport regions HTR1, HTR2, HTR3, and HTR4 may be about 10 nm to about 1000 nm, for example, about 10 nm to about 500 nm. The thickness of each of the hole injection layers HIL1, HIL2, HIL3, and HIL4 may be, for example, about 5 nm to about 100 nm. The thickness of each of the hole transport layers HTL1, HTL2, HTL3, and HTL4 may be about 5 nm to about 100 nm. When the hole transport regions HTR1, HTR2, HTR3, and HTR4 include a hole-side additional layer, the thickness of the hole-side additional layer may be about 1 nm to about 100 nm. When the thickness of the hole transport regions HTR1, HTR2, HTR3, and HTR4 and the thickness of each layer included in them satisfy the above-mentioned ranges, satisfactory hole transport characteristics may be obtained without a substantial increase in driving voltage.

In addition to the materials mentioned above, each of the hole transport regions HTR1, HTR2, HTR3, and HTR4 may further include a charge generation material to improve conductivity. The charge generation material may be uniformly (e.g., substantially uniformly) or non-uniformly dispersed within the hole transport regions HTR1, HTR2, HTR3, and HTR4. The charge generation material may be, for example, a P-type (kind) dopant. The P-type (kind) dopant may include at least one of a halogenated metal compound, a quinone derivative, a metal oxide, or a cyano group-containing compound, but one or more embodiments of the disclosure are not limited thereto. For example, the P-type (kind) dopant may contain a halogenated metal compound such as CuI and/or RbI, a quinone derivative such as TCNQ (Tetracyanoquinodimethane) and/or F4-TCNQ (2,3,5,6-tetrafluoro-7,7′8,8-tetracyanoquinodimethane), a metal oxide such as a tungsten oxide and/or a molybdenum oxide, and/or the like, but one or more embodiments of the disclosure are not limited thereto.

Each of the blue light-emitting layers BEML1, BEML2, and BEML3 and the green light-emitting layer GEML may include a host material and a dopant material. Each of the blue light-emitting layers BEML1, BEML2, and BEML3 and the green light-emitting layer GEML may include a material containing a carbazole derivative moiety or an amine derivative moiety as a hole transporting host material. Each of the blue light-emitting layers BEML1, BEML2, and BEML3 and the green light-emitting layer GEML may include a material having a nitrogen-containing aromatic ring structure, such as a pyridine derivative moiety, a pyridazine derivative moiety, a pyrimidine derivative moiety, a pyrazine derivative moiety, and/or a triazine derivative moiety, as an electron transporting host material.

Each of the blue light-emitting layers BEML1, BEML2, and BEML3 and the green light-emitting layer GEML may include an anthracene derivative, a pyrene derivative, a fluoranthene derivative, a chrysene derivative, a dihydrobenzo anthracene derivative, and/or a triphenylene derivative as a host material. In addition, each of the blue light-emitting layer BEML1, BEML2, and BEML3 and the green light-emitting layer GEML may further include a general material suitable in the art as a host material. For example, as a host material, each of the blue light-emitting layers BEML1, BEML2, and BEML3 and the green light-emitting layer GEML may include at least one of DPEPO (Bis[2-(diphenylphosphino phenyl]ether oxide), CBP (4,4′-Bis(carbazol-9-yl)biphenyl), mCP (1,3-Bis(carbazol-9-yl)benzene), PPF (2,8-Bis(diphenylphosphoryl)dibenzo[b,d]furan), TCTA (4,4′,4″-Tris(carbazol-9-yl)-triphenylamine), or TPBi (1,3,5-tris(1-phenyl-1H-benzo[d]imidazole-2-yl)benzene). However, one or more embodiments of the disclosure are not limited thereto, and for example, Alq3 (tris (8-hydroxyquinolino) aluminum), PVK (poly(N-vinylcarbazole), ADN (9,10-di(naphthalen-2-yl)anthracene), TBADN (2-tert-butyl-9,10-di(naphth-2-yl)anthracene), DSA (distyrylarylene), CDBP (4,4′-bis(9-carbazolyl)-2,2′-dimethyl-biphenyl), MADN (2-Methyl-9,10-bis(naphthalen-2-yl)anthracene), CP1 (Hexaphenyl cyclotriphosphazene), UGH2 (1,4-Bis(triphenylsilyl)benzene), DPSiO3 (Hexaphenylcyclotrisiloxane), DPSiO4 (Octaphenylcyclotetra) siloxane), and/or the like may be used as a host material.

In one or more embodiments of the disclosure, as a suitable fluorescent dopant material, the blue light-emitting layers BEML1, BEML2, and BEML3 may include a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl) vinyl) phenyl)-N-phenylbenzenamine (N-BDAVBi)), 4,4′-bis [2-(4-(N,N-diphenylamino)phenyl)vinyl]biphenyl (DPAVBi), perylene and its derivative (e.g., 2,5,8,11-Tetra-t-butylperylene (TBP)), pyrene and its derivative (e.g., 1,1-dipyrene, 1,4-dipyrenylbenzene, 1,4-Bis(N,N-Diphenylamino) pyrene), and/or the like.

The green light-emitting layer GEML may include a suitable phosphorescent dopant material. For example, a metal complex containing iridium (Ir), platinum (Pt), osmium (Os), gold (Au), titanium (Ti), zirconium (Zr), hafnium (Hf), europium (Eu), terbium (Tb), and/or thulium (Tm) may be used as a phosphorescent dopant. For example, Flrpic (iridium(III) bis (4,6-difluorophenylpyridinato-N,C2′)picolinate), Fir6 (Bis(2,4-difluorophenylpyridinato)-tetrakis (1-pyrazolyl) borate iridium (III)), or PtOEP (platinum octaethyl porphyrin) may be used as a phosphorescent dopant.

Each of the electron transport regions ETR1, ETR2, ETR3, and ETR4 may have a single-layered structure made of a single material, a single-layered structure made of a plurality of different materials, or a multi-layered structure having a plurality of layers made of a plurality of different materials. For example, at least some of the electron transport regions ETR1, ETR2, ETR3, and ETR4 may include an electron transport layer ETL4 and an electron injection layer EIL4.

Each of the electron transport regions ETR1, ETR2, ETR3, and ETR4 may be formed by using one or more suitable methods such as a vacuum deposition method, a spin coating method, a casting method, a Langmuir-Blodgett (LB) method, an inkjet printing method, a laser printing method, and/or a laser induced thermal imaging (LITI) method.

The electron transport regions ETR1, ETR2, ETR3, and ETR4 may include an anthracene-based compound. Without being limited thereto, however, each of the electron transport regions ETR1, ETR2, ETR3, and ETR4 may include, for example, Alq3 (Tris(8-hydroxyquinolinato)aluminum), 1,3,5-tri[(3-pyridyl)-phen-3-yl]benzene, T2T (2,4,6-tris(3′-(pyridin-3-yl)biphenyl-3-yl)-1,3,5-triazine), 2-(4-(N-phenylbenzoimidazol-1-yl)phenyl)-9,10-dinaphthylanthracene, TPBi (1,3,5-Tri(1-phenyl-1H-benzo[d]imidazol-2-yl)benzene), BCP (2,9-Dimethyl-4,7-diphenyl-1,10-phenanthroline), Bphen (4,7-Diphenyl-1,10-phenanthroline), TAZ (3-(4-Biphenylyl)-4-phenyl-5-tert-butylphenyl-1,2,4-triazole), NTAZ (4-(Naphthalen-1-yl)-3,5-diphenyl-4H-1,2,4-triazole), tBu-PBD (2-(4-Biphenylyl)-5-(4-tert-butylphenyl)-1,3,4-oxadiazole), BAlq (Bis (2-methyl-8-quinolinolato-N1,O8)-(1,1′-Biphenyl-4-olato)aluminum), Bebq2 (berylliumbis(benzoquinolin-10-olate)), and (9,10-di(naphthalen-2-yl)anthracene), BmPyPhB (1,3-Bis[3,5-di(pyridin-3)-yl)phenyl]benzene) and mixtures thereof.

In addition, each of the electron transport regions ETR1, ETR2, ETR3, and ETR4 may include a halogenated metal such as LiF, NaCl, CsF, RbCl, RbI, CuI, and/or KI, a lanthanide metal such as Yb, and/or a co-deposition material of the halogenated metal and the lanthanide metal. For example, the electron transport regions ETR1, ETR2, ETR3, and ETR4 may include KI:Yb, RbI:Yb, and/or the like as a co-deposition material. The electron transport region ETR1, ETR2, ETR3, and ETR4 may include two or more materials selected from among Mg, Ag, Yb, and Al. For example, the electron transport regions ETR1, ETR2, ETR3, and ETR4 may include Mg and Yb.

In one or more embodiments, the electron transport regions ETR1, ETR2, ETR3, and ETR4 may be made of a metal oxide such as Li₂O and/or BaO, Liq (8-hydroxyl-Lithium quinolate), and/or the like, but one or more embodiments of the disclosure are not limited thereto. Each of the electron transport regions ETR1, ETR2, ETR3, and ETR4 may also be made of a mixture of an electron transport material and an insulating organo metal salt. The organic metal salt may be a material having an energy band gap of about 4 eV or more. For example, the organo metal salt may include metal acetate, metal benzoate, metal acetoacetate, metal acetylacetonate, or metal stearate.

Each of the electron transport regions ETR1, ETR2, ETR3, and ETR4 may further include at least one of BCP (2,9-dimethyl-4,7-diphenyl-1,10-phenanthroline) or Bphen (4,7-diphenyl-1,10-phenanthroline) in addition to the above-mentioned materials, but one or more embodiments of the disclosure are not limited thereto.

The electron transport regions ETR1, ETR2, ETR3, and ETR4 may include the compounds of the electron transport regions described above in the electron injection layer or the electron transport layer. When the electron transport regions ETR1, ETR2, ETR3, and ETR4 include an electron-side additional layer, the electron-side additional layer may include the above-described materials. In one or more embodiments of the disclosure, the electron injection layer EIL4 may be composed of two or more materials selected from among Mg, Ag, Yb, and Al. The electron injection layer EIL4 may be composed of, for example, a mixture of Mg and Yb.

The thickness of each of the electron transport regions ETR1, ETR2, ETR3, and ETR4 may be, for example, about 10 nm to about 150 nm. The thickness of the electron transport layer may be about 0.1 nm to about 100 nm, for example, about 0.3 nm to about 50 nm. When the thickness of the electron transport layer satisfies the range described above, satisfactory electron transport characteristics may be obtained without a substantial increase in driving voltage.

The second electrode CE is provided on the plurality of light-emitting stacks ST1, ST2, ST3, and ST4. The second electrode CE may be a common electrode. The second electrode CE may be a cathode or an anode, but one or more embodiments of the disclosure are not limited thereto. For example, if (e.g., when) the first electrode AE is an anode, the second electrode CE may be a cathode, and if (e.g., when) the first electrode AE is a cathode, the second electrode CE may be an anode.

The second electrode CE may be a semi-transmissive electrode or a transmissive electrode. When the second electrode CE is a transmissive electrode, the second electrode CE may be made of a transparent metal oxide such as indium tin oxide (ITO), indium zinc oxide (IZO), zinc oxide (ZnO), and/or indium tin zinc oxide (ITZO).

When the second electrode CE is a semi-transmissive electrode or a reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, In, Zn, Sn, or a compound or mixture containing them (e.g., AgMg, AgYb, or MgAg). In one or more embodiments, the second electrode CE may have a multi-layered structure including a reflective or semi-transmissive film formed of the above materials and a transparent conductive film formed of indium tin oxide (ITO), indium zinc oxide (IZO), zinc oxide (ZnO), indium tin zinc oxide (ITZO), and/or the like. For example, the second electrode CE may include an aforementioned metal material, a combination of two or more metal materials selected from among the aforementioned metal materials, an oxide of the aforementioned metal materials, and/or the like.

In one or more embodiments, the second electrode CE may be connected to an auxiliary electrode. When the second electrode CE is connected to the auxiliary electrode, the resistance of the second electrode CE may be reduced.

In one or more embodiments, a capping layer CPL may be further arranged on the second electrode CE of the light-emitting element LED according to one or more embodiments of the disclosure. The capping layer CPL may include a plurality of layers or a single layer.

In one or more embodiments of the disclosure, the capping layer CPL may be an organic layer or an inorganic layer. For example, if (e.g., when) the capping layer CPL includes an inorganic material, the inorganic material may include an alkali metal compound such as LiF, an alkaline earth metal compound such as MgF₂, SiON, SiNₓ, SiO_{y}, and/or the like.

For example, if (e.g., when) the capping layer CPL includes an organic material, the organic material may include α-NPD, NPB, TPD, m-MTDATA, Alq₃, CuPc, TPD15 (N4,N4,N4′,N4′-tetra (biphenyl-4-yl) biphenyl-4,4′-diamine), TCTA (4,4′,4″-Tris (carbazol sol-9-yl) triphenylamine), and/or the like, or may include epoxy resin or acrylate such as methacrylate.

In one or more embodiments, the refractive index of the capping layer CPL

may be about 1.6 or more. For example, the refractive index of the capping layer CPL may be about 1.6 or more with respect to light in a wavelength range of about 550 nm to about 660 nm.

Referring again to FIG. 7, in the light-emitting element LED according to one or more embodiments of the disclosure, a functional layer FNL may be arranged between the first electrode AE and the second electrode CE. Referring to FIG. 7, the functional layer FNL may be arranged as a common layer so as to entirely overlap (e.g., to overlap all of) the light-emitting regions EA1, EA2, and EA3 and the pixel defining film PDL that separates the light-emitting regions EA1, EA2, and EA3. However, one or more embodiments of the disclosure are not limited thereto, and the functional layer FNL may be patterned and provided so as to be separately arranged to correspond to each of the light-emitting regions EA1, EA2, and EA3. In one or more embodiments, some of a plurality of organic layers included in the functional layer FNL may be patterned so as to be separately arranged to correspond to each of the light-emitting regions EA1, EA2, and EA3, and the remainder may be arranged as a common layer so as to entirely overlap (e.g., to overlap all of) the light-emitting regions EA1, EA2, and EA3 and the pixel defining film PDL.

The second electrode CE is provided on the functional layer FNL. The second electrode CE may be a common electrode. The second electrode CE may be a cathode or an anode, but one or more embodiments of the disclosure are not limited thereto. For example, if (e.g., when) the first electrode AE is an anode, the second electrode CE may be a cathode, and if (e.g., when) the first electrode AE is a cathode, the second electrode CE may be an anode. The second electrode CE may be a transmissive electrode, a semi-transmissive electrode, or a reflective electrode.

An encapsulation layer TFE may be arranged on the light-emitting element LED. For example, in one or more embodiments of the disclosure, the encapsulation layer TFE may be arranged on the second electrode CE. In addition, if (e.g., when) the light-emitting element LED includes a capping layer, the encapsulation layer TFE may be arranged on the capping layer. As described above, the encapsulation layer TFE may include at least one organic encapsulation film and at least one inorganic encapsulation film, and the inorganic encapsulation film and the organic encapsulation film may be alternately arranged.

The display panel DP according to one or more embodiments of the disclosure may include an optical layer OSL arranged on the display element layer DP-LED. The optical layer OSL may include a light control layer CCL, a color filter layer CFL, and a base layer BL.

The light control layer CCL may include a light converter. The light converter may be a quantum dot, a phosphor, and/or the like. The light converter may convert the wavelength of received light to a different wavelength and emit the converted light.

For example, the light control layer CCL may be a layer at least partially including a quantum dot or a phosphor.

The light control layer CCL may include a plurality of light control patterns CCP-R, CCP-G, and CCP-B. The light control patterns CCP-R, CCP-G, and CCP-B may be spaced and/or apart (e.g., spaced apart or separated) from each other. The light control patterns CCP-R, CCP-G, and CCP-B may be arranged to be spaced and/or apart (e.g., spaced apart or separated) from each other by the bank BMP. The light control patterns CCP-R, CCP-G, and CCP-B may be arranged in the bank openings BOH1, BOH2, and BOH3 defined in the bank BMP. However, one or more embodiments of the disclosure are not limited thereto. FIG. 7 illustrates that the bank BMP does not overlap (non-overlaps) the light control patterns CCP-R, CCP-G, and CCP-B and has a rectangular shape on a cross section, but the edges of some of the light control patterns CCP-R, CCP-G, and CCP-B may at least partially overlap the bank BMP. For example, the edge of the third light control pattern CCP-B may be arranged to overlap the bank BMP on a plane (e.g., in a plan view). The bank BMP may have a trapezoidal shape on a cross section. The bank BMP may have a shape in which the cross-sectional width of the bank BMP increases as it approaches the display element layer DP-LED.

The light control patterns CCP-R, CCP-G, and CCP-B may convert the wavelength of light provided from the display element layer DP-LED or transmit the light provided.

The light control layer CCL may include a first light control pattern CCP-R that provides red light as a first light, a second light control pattern CCP-G that provides green light as a second light, and a third light control pattern CCP-B that provides blue light as a third light. The light control layer CCL may include a first light control pattern CCP-R that converts the source light provided from the light-emitting element LED into a first light, a second light control pattern CCP-G that converts the source light into a second light, and a third light control pattern CCP-B that transmits the source light. The source light may be blue light. At least some of the light control patterns CCP-R, CCP-G, and CCP-B may include a quantum dot that converts the source light into light of a specific (e.g., set or predetermined) wavelength.

At least some of the light control patterns CCP-R, CCP-G, and CCP-B may

be formed through an inkjet process. In one or more embodiments, some of the light control patterns CCP-R, CCP-G, and CCP-B may be formed through a photoresist process.

The light control layer CCL may further include a scatterer. The first light control pattern CCP-R may include a first quantum dot and a scatterer, the second light control pattern CCP-G may include a second quantum dot and a scatterer, and the third light control pattern CCP-B may not include (e.g., may exclude) a quantum dot, but may include a scatterer. Each of the first light control pattern CCP-R, the second light control pattern CCP-G, and the third light control pattern CCP-B may further include a base resin that disperses quantum dots and scatterers. In one or more embodiments, as the third light control pattern CCP-B is formed through a photoresist process which will be described in more detail later, the third light control pattern CCP-B may include a photosensitive resin.

The light control layer CCL may include a first barrier layer CAP1 arranged on one side of the first light control pattern CCP-R. The light control layer CCL may include a first barrier layer CAP1 spaced and/or apart (e.g., spaced apart or separated) from the display element layer DP-LED with the first light control pattern CCP-R interposed therebetween and a second barrier layer CAP2 adjacent to the display element layer DP-LED.

In the display panel DP, the optical layer OSL includes a color filter layer CFL arranged on the light control layer CCL. The color filter layer CFL may include color filters CF1, CF2, and CF3. The color filter layer CFL may include a first color filter CF1 configured to transmit a first light, a second color filter CF2 configured to transmit a second light, and a third color filter CF3 configured to transmit the source light. In one or more embodiments of the disclosure, the first color filter CF1 may be a red filter, the second color filter CF2 may be a green filter, and the third color filter CF3 may be a blue filter.

Each of the color filters CF1, CF2, and CF3 includes a polymer photosensitive resin and a colorant. The first color filter CF1 may include a red colorant, the second color filter CF2 may include a green colorant, and the third color filter CF3 may include a blue colorant. The first color filter CF1 may include a red pigment and/or a red dye, the second color filter CF2 may include a green pigment and/or a green dye, and the third color filter CF3 may include a blue pigment and/or a blue dye.

The first to third color filters CF1, CF2, and CF3 may be respectively arranged to correspond to the first sub-pixel region PXA-1, the second sub-pixel region PXA-2, and the third sub-pixel region PXA-3. In addition, the first to third color filters CF1, CF2, and CF3 may be respectively arranged to correspond to the first to third light control patterns CCP-R, CCP-G, and CCP-B.

In addition, the plurality of color filters CF1, CF2, and CF3 that transmit different light may be arranged to overlap each other in the non-pixel region NPXA arranged between the pixel regions PXA-1, PXA-2, and PXA-3. As the plurality of color filters CF1, CF2, and CF3 are arranged to overlap each other in the third direction DR3, which is the thickness direction, boundaries between adjacent pixel regions PXA-1, PXA-2, and PXA-3 may be demarcated. In one or more embodiments, unlike what is illustrated, the color filter layer CFL may include a light blocking portion to demarcate boundaries between adjacent color filters CF1, CF2, and CF3. The light blocking portion may be formed of a blue filter, or may be formed by including an organic light blocking material or an inorganic light blocking material that contains a black pigment or a black dye.

The optical layer OSL may include a low refractive layer LR arranged between the light control layer CCL and the color filter layer CFL. The low refractive layer LR may be arranged between the light control patterns CCP-R, CCP-G, and CCP-B and the color filters CF1, CF2, and CF3. The low refractive layer LR may be arranged on the light control layer CCL and block or protect the light control patterns CCP-R, CCP-G, and CCP-B from being exposed to moisture/oxygen. In addition, by being arranged between the light control patterns CCP-R, CCP-G, and CCP-B and the color filters CF1, CF2, and CF3, the low refractive layer LR may also function as an optical functional layer to increase light extraction efficiency or prevent or reduce reflected light from being incident on the light control layer CCL. The low refractive layer LR may have a lower refractive index than other adjacent layers.

In one or more embodiments of the disclosure, the optical layer OSL may further include a base layer BL arranged on the color filter layer CFL. The base layer BL may be a member that provides a base surface on which the color filter layer CFL and the light control layer CCL are arranged. The base layer BL may be a glass substrate, a metal substrate, or a plastic substrate. However, one or more embodiments of the disclosure are not limited thereto, and the base layer BL may be an inorganic layer, an organic layer, or a composite material layer. In addition, alternatively, in one or more embodiments of the disclosure, the base layer BL may not be provided.

The display device DD may further include a filling layer FML arranged between the optical layer OSL and the display panel DP. In one or more embodiments of the disclosure, the filling layer FML may fill a space between the optical layer OSL and the display panel DP.

The filling layer FML may function as a buffer between the optical layer OSL and the display panel DP. In one or more embodiments of the disclosure, the filling layer FML may function as a shock absorber and increase the strength of the display panel DP. The filling layer FML may be formed from a filling resin including a polymer resin. For example, the filling layer FML may be formed from a filling layer resin including an acrylic-based resin or an epoxy-based resin.

In one or more embodiments, an open portion OPP overlapping the transmission region TA is provided in the bank BMP. A portion of the filling layer FML may be arranged in the open portion OPP provided in the bank BMP. A portion of the optical layer OSL that overlaps the transmission region TA may not overlap the light control patterns CCP-R, CCP-G, and CCP-B, the bank BMP, and the color filters CF1, CF2, and CF3, and a portion of the optically transparent filling layer FML may be arranged in the portion of the optical layer OSL that overlaps the transmission region

TA. The filling layer FML having a larger thickness (e.g., than other areas) may be provided to correspond to the transmission region TA and may also function as an optical functional layer to increase light extraction efficiency or prevent or reduce reflected light from entering the lower portion thereof. A filling pattern FLP (e.g., the filling layer FML) may have a lower refractive index than other adjacent layers.

In one or more embodiments, in order to improve the transmittance of the transmission region TA in the display panel DP, at least some of the insulating layers arranged in the transmission region TA may be removed.

According to this embodiment, the base substrate BS, the first insulating layer 10, the second insulating layer 20, and the third insulating layer 30 may be arranged in the transmission region TA. A transmission opening T-OP that overlaps the transmission region TA may be defined in the fourth insulating layer 40, the fifth insulating layer 50, the pixel defining film PDL, and the light-emitting element LED. The transmission opening T-OP may be defined by side surfaces formed in penetrated portions of the fourth insulating layer 40, the fifth insulating layer 50, the pixel defining film PDL, and the light-emitting element LED which overlap the transmission region TA. The transmission opening T-OP may be formed by removing a portion of each of the fourth insulating layer 40, the fifth insulating layer 50, the pixel defining film PDL, and the light-emitting element LED through a dry etching process. The transmission opening T-OP may extend along the second direction DR2. For example, the transmission opening T-OP may be provided to correspond to both (e.g., simultaneously) a plurality of transmission regions TA arranged along the second direction DR2 and middle regions MA arranged between them.

In one or more embodiments, at least a portion of the functional layer FNL included in the light-emitting element LED may be removed through an etching process. As described above, the light-emitting element LED may include the plurality of light-emitting stacks ST1, ST2, ST3, and ST4 respectively including the light-emitting layers BEML1, BEML2, BEML3, and GEML, and at least some of the plurality of light-emitting stacks ST1, ST2, ST3, and ST4 may be removed from the transmission region TA corresponding to the transmission opening T-OP. Accordingly, at least some of the light-emitting layers BEML1, BEML2, BEML3, and GEML respectively included in the plurality of light-emitting stacks ST1, ST2, ST3, and ST4 may not overlap the transmission region TA.

In this embodiment, the upper surface of the third insulating layer 30 may be exposed from the fourth insulating layer 40, the fifth insulating layer 50, the pixel defining film PDL, and the light-emitting element LED through the transmission opening T-OP. An inorganic encapsulation film and/or the like included in the encapsulation layer TFE may be arranged on the upper surface of the third insulating layer 30. An organic encapsulation film T-OL included in the encapsulation layer TFE may be arranged within the transmission opening T-OP.

The description of the above-mentioned transmission region TA may be commonly applied to the unit regions PU described in FIG. 3. Therefore, on a plane (e.g., in a plan view), a plurality of openings arranged to be spaced and/or apart (e.g., spaced apart or separated) from each other along the first direction DR1 and the second direction DR2 may be defined in the fourth insulating layer 40, the fifth insulating layer 50, the pixel defining film PDL, and the light-emitting element LED. The openings may be arranged along the first direction DR1 and the second direction DR2 on a plane (e.g., in a plan view).

According to this disclosure, the fourth insulating layer 40 containing silicon nitride may not be arranged in the transmission region TA of the display panel DP included in the transparent display device. Accordingly, the transmittance of the transmission region TA may be improved.

In one or more embodiments, FIG. 7 illustrates that the transmission opening T-OP corresponding to the transmission region TA is defined in each of the fourth insulating layer 40, the fifth insulating layer 50, the pixel defining film PDL, and the light-emitting element LED, but one or more embodiments of the disclosure are not limited thereto, and the transmission opening T-OP may be additionally formed in another insulating layer included in the circuit element layer DP-CL. In one or more embodiments, the transmission opening T-OP may not be defined in some of the fourth insulating layer 40, the fifth insulating layer 50, the pixel defining film PDL, and the light-emitting element LED. For example, some optically transparent layers of the functional layer FNL included in the light-emitting element LED may not be removed from a portion corresponding to the transmission opening T-OP.

FIGS. 9A and 9B are cross-sectional views of a portion of an optical layer according to one or more embodiments of the disclosure. FIG. 9A illustrates a cross-section of the optical layer OSL corresponding to the line III-III′ of FIG. 5B. FIG. 9B illustrates a cross section of the optical layer OSL corresponding to the line IV-IV′ of FIG. 5B. For the convenience of explanation, in FIGS. 9A and 9B, the third direction DR3 is illustrated to indicate a downward direction. For example, a cross section turned upside down from the cross section illustrated in FIGS. 6 and 7 is illustrated, and the third direction DR3 is described as an upward direction, and the direction opposite to the third direction DR3 is described as a downward direction.

Referring to FIGS. 5B, 6, 7, 9A, and 9B together, the optical layer OSL includes a blocking pattern BP. The blocking pattern BP may be arranged to correspond to at least the middle region MA provided between the transmission regions TA. The blocking pattern BP may overlap at least the middle region MA on a plane (e.g., in a plan view). The blocking pattern BP may include a first blocking pattern BP1 arranged in the first middle region MA1. The blocking pattern BP may include a second blocking pattern BP2 arranged in the second middle region MA2, a third blocking pattern BP3 arranged in the third middle region MA3, and a fourth blocking pattern BP4 arranged in the fourth middle region MA4. In FIGS. 9A and 9B, for the convenience of explanation, each of the first to fourth blocking patterns BP1, BP2, BP3, and BP4 illustrated in FIG. 5A is illustrated as a “blocking pattern BP”, each of the transmission regions TA1, TA2, TA3, TA4, TA5, and TA6 included in each of the unit regions PU is illustrated as a “transmission region TA”, and each of the first to fourth middle regions MA1, MA2, MA3, and MA4 in which the blocking pattern BP is arranged is illustrated as a “middle region MA”.

The blocking pattern BP may be arranged below the low refractive layer LR. The blocking pattern BP may be arranged directly below the second barrier layer CAP2.

As illustrated in FIG. 9B, at least a portion of the blocking pattern BP is arranged in the open portion OPP provided in the bank BMP. At least a portion of the blocking pattern BP may be arranged between the inner side surface BMP-S of the bank BMP defining the open portion OPP. At least a portion of the blocking pattern BP may be arranged directly below the second barrier layer CAP2 arranged in the open portion OPP.

The blocking pattern BP may include an optically transparent material. The blocking pattern BP may have a light transmittance of about 80% to about 99% in the visible light wavelength range. As the blocking pattern BP includes an optically transparent material, the transmittance of the display device DD may not decrease although a portion of the blocking pattern BP overlaps the transmission region TA and the middle region MA.

The blocking pattern BP may include a blocking portion BPP arranged in the open portion OPP and a spacer portion SPP overlapping the bank BMP on a plane (e.g., in a plan view). The spacer portion SPP may be arranged below the bank BMP. The spacer portion SPP may be arranged directly below the second barrier layer CAP2 arranged below the bank BMP. The spacer portion SPP may be provided to maintain a gap between the optical layer OSL and the display panel DP in a bonding process of the optical layer OSL and the display panel DP and support the components included in the optical layer OSL and the display panel DP so that they are not damaged at an intermediate stage of the process.

The blocking portion BPP and the spacer portion SPP may include a same material. The blocking portion BPP and the spacer portion SPP may be formed together through a same process. As illustrated in FIG. 9B, the blocking portion BPP and the spacer portion SPP may be connected to each other and have an integral shape. That is, the spacer portion SPP and the blocking portion BPP may be integrally connected to form a single integral unit. A portion of the blocking portion BPP may extend to be arranged on the second barrier layer CAP2 arranged on the inner side surface BMP-S of the bank BMP and be connected to the spacer portion SPP arranged below the bank BMP.

The blocking pattern BP may have a smaller thickness than the bank BMP. The blocking pattern BP may have a smaller thickness than each of the bank BMP and the light control pattern CCP-R included in the light control layer CCL.

As the optical layer OSL of the display device according to one or more embodiments of the disclosure includes the blocking pattern BP arranged to correspond to the middle region MA provided between the transmission regions TA, the durability of the display device may be improved. For example, in the display device according to one or more embodiments of the disclosure, if (e.g., when) a peeling phenomenon occurs in a portion of the organic encapsulation film T-OL of the encapsulating layer TFE of the display panel DP, the blocking pattern BP included in the optical layer OSL may prevent or reduce the peeling of the organic encapsulation film T-OL from spreading in one direction (for example, the second direction DR2), thereby improving the durability of the display device. In other words, the optical layer OSL of the display device includes a blocking pattern BP that corresponds to the middle region MA between transmission regions TA. This blocking pattern overlaps the middle region and includes multiple sub-patterns (BP1, BP2, BP3, and BP4) arranged in different middle regions. The blocking pattern is positioned below the low refractive layer LR and directly beneath the second barrier layer CAP2. Portions of the blocking pattern are located in the open portion OPP of the bank BMP and between the inner side surface of the bank and the second barrier layer. The blocking pattern is made of an optically transparent material with high light transmittance (about 80%-about 99%), ensuring the display device's transmittance is not compromised. It includes a blocking portion BPP and a spacer portion SPP, both made from the same material and formed together. The blocking pattern is thinner than the bank and the light control pattern CCP-R. This configuration helps prevent or reduce the spread of peeling in the organic encapsulation film, thereby enhancing the display device's durability.

Referring again to FIGS. 5B, 6, 7, 9A, and 9B, in the display panel of the display device according to one or more embodiments of the disclosure, if (e.g., when) a foreign matter exists between the organic encapsulation film T-OL of the encapsulation layer TFE and the first inorganic encapsulation film T-IOL1 arranged therebelow, a peeling phenomenon may occur between the organic encapsulation film T-OL and the first inorganic encapsulation film T-IOL1 arranged therebelow in a process of bonding and heat-treating the display panel DP and the optical layer OSL, and the peeling that has occurred may spread in one direction. For example, in the transmission region TA and the middle region MA provided between the transmission regions TA, a transmission opening T-OP is defined and the encapsulation layer TFE is formed to be thicker than other portions, so that a peeling phenomenon is likely to occur between the organic encapsulation film T-OL and the first inorganic encapsulation film T-IOL1 arranged therebelow and the peeling may easily spread in one direction.

When a peeling phenomenon occurs in the transmission region TA of a related art (typical) display device, as the fourth insulating layer 40, the fifth insulating layer 50, and the pixel defining film PDL of the display panel DP, which have a large thickness, are provided on both sides (e.g., opposite sides) of the transmission region TA with respect to the first direction DR1 and the bank BMP of the optical layer OSL is also arranged, the peeling does not easily spread in the first direction DR1. However, with respect to the second direction DR2, as the transmission opening T-OP of the display panel DP extends in this direction and the open portion OPP of the optical layer OSL also extends in this direction, the peeling that occurs between the organic encapsulation film T-OL and the first inorganic encapsulation film T-IOL1 arranged therebelow may spread along the second direction DR2 without being blocked (e.g., without much resistance). However, in the case of the display device according to one or more embodiments of the disclosure, as the optical layer OSL includes a blocking pattern BP arranged to correspond to the middle region MA provided between the transmission regions TA, the thickness (e.g., total thickness) of the encapsulation layer TFE and filling layer FML is reduced by the blocking pattern BP in the middle region MA, and therefore, the peeling that occurs in a portion of the transmission region TA may be blocked by a portion in which the blocking pattern BP is arranged. For example, in the display device according to one or more embodiments of the disclosure, the peeling that occurs in a portion of the transmission region TA along the second direction DR2 may be prevented or reduced from spreading, thus improving the durability of the display device.

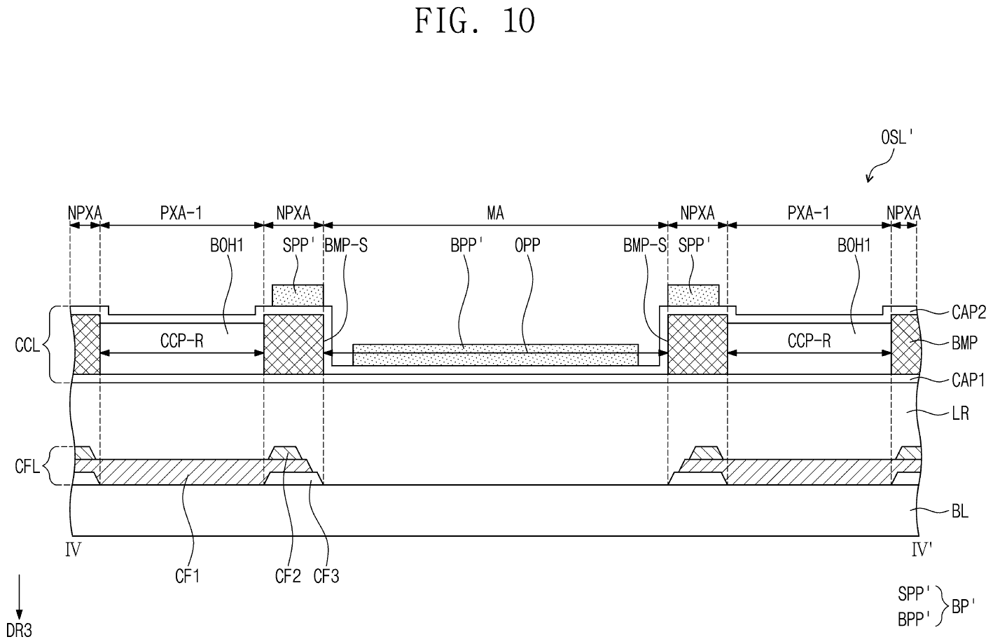

FIG. 10 is a cross-sectional view of some components of an optical layer according to one or more embodiments of the disclosure. In FIG. 10, a cross section of the optical layer corresponding to the line IV-IV′ of FIG. 5B is illustrated as in FIG. 9B, but FIG. 10 illustrates an optical layer OSL′ according to one or more embodiments of the disclosure, which is different from one or more embodiments illustrated in FIG. 9B.

Referring to FIG. 10, unlike the blocking pattern BP illustrated in FIG. 9B, a blocking portion BPP′ and a spacer portion SPP′ in a blocking pattern BP′ according to one or more embodiments of the disclosure may not have an integral shape. The blocking portion BPP′ and the spacer portion SPP′ may be spaced and/or apart (e.g., spaced apart or separated) from each other in one direction. The blocking portion BPP′ may be arranged within the open portion OPP and may be spaced and/or apart (e.g., spaced apart or separated) from the inner side surface BMP-S of the bank BMP at a set or predetermined distance. The spacer portion SPP′ may overlap the bank BMP on a plane (e.g., in a plan view). The spacer portion SPP′ may be patterned to be arranged only in a portion below the bank BMP.

The blocking portion BPP′ and the spacer portion SPP′ may include a same material. The blocking portion BPP′ and the spacer portion SPP′ may be formed together through a same process. The blocking portion BPP′ and the spacer portion SPP′ may be formed through a same process, but may be formed by being patterned so as to be spaced and/or apart (e.g., spaced apart or separated) from each other.

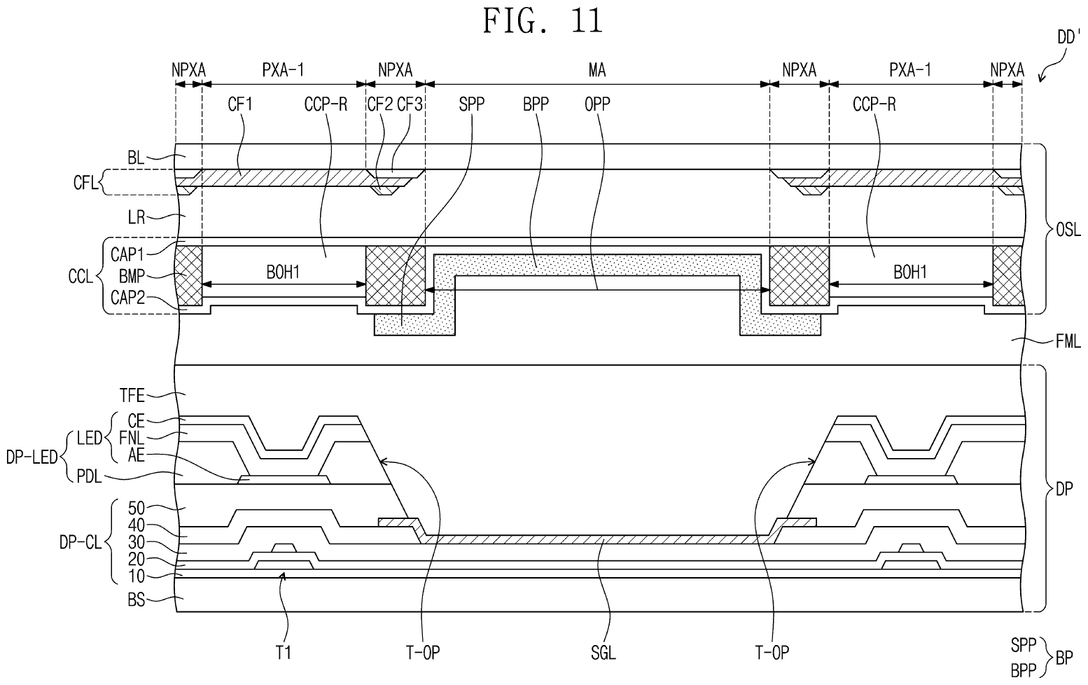

FIG. 11 is a cross-sectional view of a portion of a display device DD′ according to one or more embodiments of the disclosure. FIG. 11 illustrates a cross section of the display device DD′ corresponding to the line IV-IV′ of FIG. 5B and illustrates a cross-sectional structure of the display device DD′ including the optical layer OSL described in FIG. 9B.

Referring to FIGS. 9B and 11 together, the display panel DP of the display device DD′ according to one or more embodiments of the disclosure may include a signal line SGL arranged in the middle region MA. The signal line SGL may be (e.g., represent) a region that electrically connects adjacent pixels to each other. The signal line SGL may include lines such as the above-described sensing line, power line, data line, and/or scan line. The signal line SGL may be electrically connected to each light-emitting element LED included in each adjacent pixel.

Referring to FIGS. 5A, 9B, and 11 together, each middle region MA may correspond to a line region. Each middle region MA may be a region in which a signal line SGL including lines such as the above-described sensing line, power line, data line, and/or scan line is arranged. A blocking pattern BP is arranged in the middle region MA, and at least a portion of the blocking pattern BP may overlap the signal line SGL on a plane (e.g., in a plan view). In the display device DD′ according to one or more embodiments of the disclosure, the blocking pattern BP is arranged to correspond to the middle region MA in which the signal line SGL is arranged, and therefore, it is possible to secure a region having as high as possible a transmittance (e.g., the maximum transmittance) among a region corresponding to the open portion OPP and the transmission opening T-OP. Accordingly, the transmittance of the transparent display device DD′ may be improved.

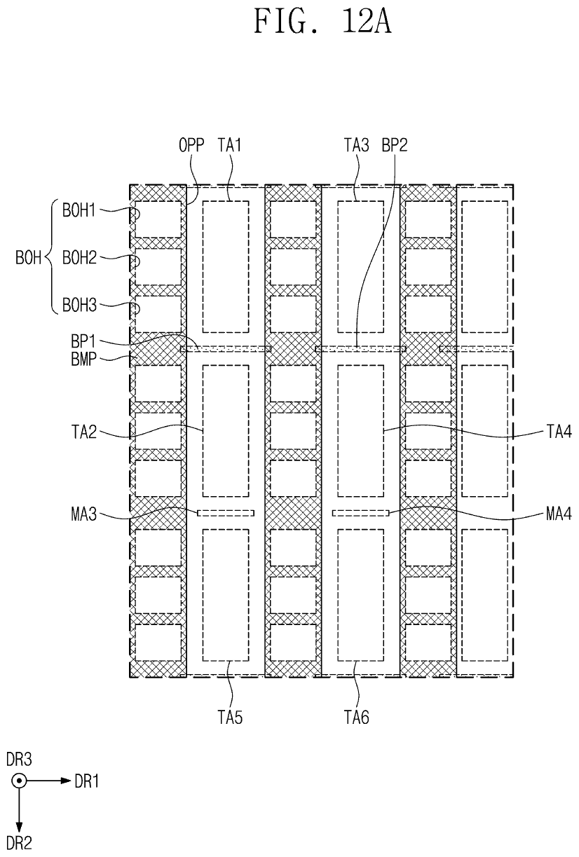

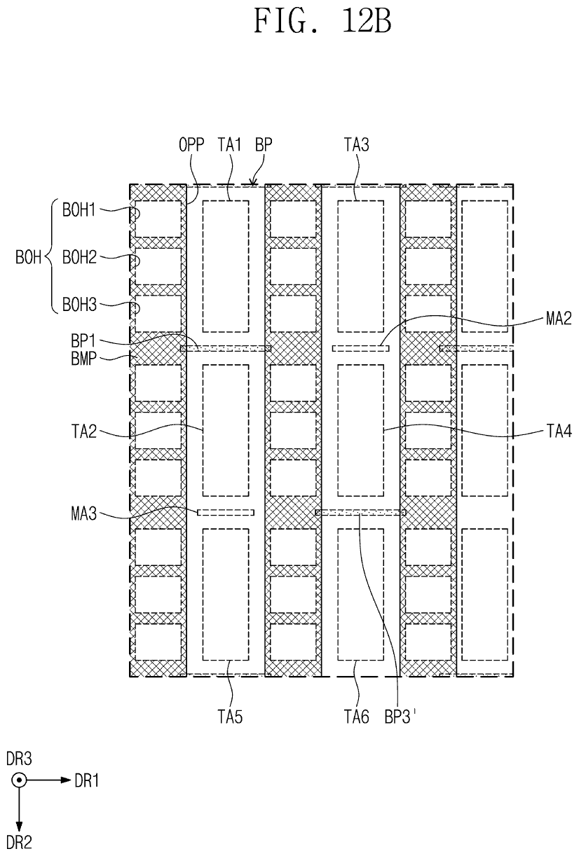

FIGS. 12A and 12B are enlarged plan views of some components of the display device according to one or more embodiments of the disclosure. Each of FIGS. 12A and 12B illustrates the planar arrangement shape of the bank BMP and the blocking pattern BP corresponding to one or more embodiments different from one or more embodiments illustrated in FIG. 5B.

Referring to FIGS. 5A, 5B, 12A, and 12B together, open portions OPP corresponding to the transmission regions TA may be defined in the bank BMP, and the open portions OPP may correspond to both (e.g., simultaneously) the plurality of transmission regions TA arranged along the second direction DR2 and the middle regions MA arranged between them.

The blocking pattern BP may be arranged to correspond to at least a portion of the above-described middle region MA. The blocking pattern BP may overlap at least a portion of the middle region MA.

In one or more embodiments of the disclosure, as illustrated in FIG. 5B, the blocking pattern BP may be provided to entirely overlap the middle region MA (e.g., the blocking pattern BP may be provided to overlap the entire middle region MA). The blocking pattern BP may include a first blocking pattern BP1 arranged in the first middle region MA1, a second blocking pattern BP2 arranged in the second middle region MA2, a third blocking pattern BP3 arranged in the third middle region MA3, and a fourth blocking pattern BP4 arranged in the fourth middle region MA4.

In one or more embodiments, the blocking pattern BP may be provided to overlap only a portion of the middle region MA. As illustrated in FIG. 12A, the blocking pattern BP may include a first blocking pattern BP1 arranged in the first middle region MA1 and a second blocking pattern BP2 arranged in the second middle region MA2. Blocking patterns may not overlap the third middle region MA3 and the fourth middle region MA4. The blocking patterns may not be provided in the third middle region MA3 and the fourth middle region MA4. In one or more embodiments, as illustrated in FIG. 12B, the blocking pattern BP may include a first blocking pattern BP1 arranged in the first middle region MA1 and a third blocking pattern BP3′ arranged in the fourth middle region MA4. Blocking patterns may not overlap the second middle region MA2 and the third middle region MA3. The blocking patterns may not be provided in the second middle region MA2 and the third middle region MA3.

According to one or more embodiments of the disclosure, as the ratio (e.g., area ratio) of the transmission region within the display region increases, the transmittance of the display device may be improved, and if (e.g., when) a peeling phenomenon occurs between an organic film and an inorganic film in the encapsulation layer of the display panel, it is also possible to prevent or reduce the peeling from spreading in one direction. Therefore, the durability of the display device may be improved.

In the context of the present application and unless otherwise defined, the terms “use,” “using,” and “used” may be considered synonymous with the terms “utilize,” “utilizing,” and “utilized,” respectively.

The use of “may” when describing embodiments of the inventive concept refers to “one or more embodiments of the inventive concept.” Throughout the disclosure, the expression “at least one of a, b or c”, “at least one selected from a, b, and c”, “at least one selected from the group consisting of a, b, and c”, “at least one from among a, b, and c”, “at least one selected from among a, b, and c”, etc., indicates only a, only b, only c, both (e.g., simultaneously) a and b, both (e.g., simultaneously) a and c, both (e.g., simultaneously) b and c, all of a, b, and c, or variations thereof.

As used herein, the term “about,” and similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A display device, a device for manufacturing the same, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Although the above has been described with reference to embodiments of the disclosure, those skilled in the art or those of ordinary skill in the art will understand that one or more suitable modifications and changes can be made to the disclosure within the scope that does not depart from the spirit and technical field of the disclosure described in the claims to be described in more detail later. Accordingly, the technical scope of the disclosure should not be limited to the content (e.g., amount) described in the detailed description of the specification, but should be determined by the claims described hereinafter, or equivalents thereof.

1 what is claimed is:

1. A display device comprising:
a display panel comprising a plurality of unit regions each comprising a plurality of pixel regions and a transmission region adjacent to the plurality of pixel regions, the display panel being to provide a source light; and
an optical layer on the display panel and to transmit the source light or to convert the source light into light of a different wavelength,
wherein the plurality of unit regions comprise:
a first unit region comprising a plurality of first pixel regions and a first transmission region adjacent to the plurality of first pixel regions along a first direction; and
a second unit region adjacent to the first unit region along a second direction crossing the first direction, the second unit region comprising a plurality of second pixel regions and a second transmission region adjacent to the plurality of second pixel regions along the first direction,
wherein:
the first transmission region and the second transmission region are adjacent to each other along the second direction;
a first middle region is defined between the first transmission region and the second transmission region; and
the optical layer comprises a blocking pattern that overlaps the first middle region in a plan view of the display device.

2. The display device of claim 1,
wherein the optical layer further comprises a light control layer,
wherein the light control layer comprises:
a bank on the display panel and having a plurality of bank openings defined therein, the plurality of bank openings respectively corresponding to the plurality of pixel regions; and
a plurality of light control patterns respectively inside the plurality of bank openings.

3. The display device of claim 2, wherein:
the bank further has an open portion corresponding to the transmission region; and
at least a portion of the blocking pattern is within the open portion.

4. The display device of claim 3,
wherein the blocking pattern comprises:
a blocking portion within the open portion; and
a spacer portion overlapping the bank in the plan view, and
wherein the blocking portion and the spacer portion comprise a same material.

5. The display device of claim 4, wherein the spacer portion and the blocking portion are internally connected to each other to be a single integral unit.

6. The display device of claim 4, wherein the blocking portion is spaced from an inner side surface of the bank defining the open portion.

7. The display device of claim 2, wherein a thickness of the blocking pattern is smaller than a thickness of the bank.

8. The display device of claim 2, wherein the optical layer further comprises a color filter layer on the light control layer and comprising a plurality of color filters.

9. The display device of claim 1,
wherein the plurality of unit regions further comprise:
a third unit region adjacent to the first unit region along the first direction, the third unit region comprising a plurality of third pixel regions and a third transmission region adjacent to the plurality of third pixel regions along the first direction; and
a fourth unit region adjacent to the third unit region along the second direction, the fourth unit region comprising a plurality of fourth pixel regions and a fourth transmission region adjacent to the plurality of fourth pixel regions along the first direction,
wherein:
the third transmission region and the fourth transmission region are adjacent to each other along the second direction; and
a second middle region is defined between the third transmission region and the fourth transmission region, and
wherein the blocking pattern comprises:
a first blocking pattern overlapping the first middle region; and
a second blocking pattern overlapping the second middle region.

10. The display device of claim 9,
wherein the plurality of unit regions further comprise:
a fifth unit region adjacent to the second unit region along the second direction, the fifth unit region comprising a plurality of fifth pixel regions and a fifth transmission region adjacent to the plurality of fifth pixel regions along the first direction; and
a sixth unit region adjacent to the fifth unit region along the first direction, the sixth unit region comprising a plurality of sixth pixel regions and a sixth transmission region adjacent to the plurality of sixth pixel regions along the first direction, and
wherein:
the second transmission region and the fifth transmission region are adjacent to each other along the second direction;
a third middle region is defined between the second transmission region and the fifth transmission region; and
the blocking pattern does not overlap the third middle region.

11. The display device of claim 10, wherein:
the fourth transmission region and the sixth transmission region are adjacent to each other along the second direction; and
a fourth middle region is defined between the fourth transmission region and the sixth transmission region, and
wherein the blocking pattern comprises:
a first blocking pattern overlapping the first middle region; and
a third blocking pattern overlapping the fourth middle region.

12. The display device of claim 1, wherein the blocking pattern comprises an optically transparent material.

13. The display device of claim 1, wherein the plurality of pixel regions comprise a first sub-pixel region, a second sub-pixel region, and a third sub-pixel region sequentially arranged along the second direction, and
wherein the transmission region overlaps each of the first sub-pixel region, the second sub-pixel region, and the third sub-pixel region in the first direction.

14. The display device of claim 1, further comprising a filler between the display panel and the optical layer.

15. The display device of claim 1,
wherein the display panel comprises:
a plurality of light-emitting elements that generate the source light; and
signal lines at least partially electrically connected to the plurality of light-emitting elements, and
wherein at least some of the signal lines overlap the blocking pattern in the plan view.

16. The display device of claim 15,
wherein the display panel further comprises an encapsulation layer covering the plurality of light-emitting elements, and
wherein the encapsulation layer comprises at least one inorganic encapsulation film and at least one organic encapsulation film.

17. The display device of claim 15, wherein the display panel further comprises a pixel defining film, the pixel defining film having a transmission opening corresponding to the transmission region and a light-emitting opening in which each of the plurality of light-emitting elements is arranged.

18. A display device comprising:
a display panel comprising a plurality of unit regions each comprising a plurality of pixel regions and a transmission region adjacent to the plurality of pixel regions, the display panel being to provide a source light; and
an optical layer on the display panel and to transmit the source light or to convert the source light into light of a different wavelength,
wherein the plurality of unit regions comprise:
a first unit region comprising a plurality of first pixel regions and a first transmission region adjacent to the plurality of first pixel regions along a first direction; and
a second unit region adjacent to the first unit region along a second direction crossing the first direction, the second unit region comprising a plurality of second pixel regions and a second transmission region adjacent to the plurality of second pixel regions along the first direction,
wherein the optical layer comprises:
a light control layer comprising a bank, the bank having a plurality of bank openings respectively corresponding to the plurality of pixel regions and an open portion corresponding to the transmission region, and a plurality of light control patterns respectively inside the plurality of bank openings; and
a blocking pattern at least partially within the open portion and between the first transmission region and the second transmission region in a plan view of the display device.

19. The display device of claim 18, wherein the blocking pattern comprises an optically transparent material.

20. A display device comprising:
a display panel comprising a plurality of unit regions each comprising a plurality of pixel regions and a transmission region adjacent to the plurality of pixel regions, the display panel being to provide a source light; and
an optical layer on the display panel and to transmit the source light or to convert the source light into light of a different wavelength,
wherein the plurality of unit regions comprise:
a first unit region comprising a plurality of first pixel regions and a first transmission region adjacent to the plurality of first pixel regions along a first direction; and
a second unit region adjacent to the first unit region along a second direction crossing the first direction, the second unit region comprising a plurality of second pixel regions and a second transmission region adjacent to the plurality of second pixel regions along the first direction,
wherein the optical layer comprises:
a bank having a plurality of bank openings respectively corresponding to the plurality of pixel regions and an open portion corresponding to the transmission region; and
a blocking pattern partially between the first transmission region and the second transmission region in a plan view of the display device, and
wherein the blocking pattern comprises:
a blocking portion between the first transmission region and the second transmission region in the plan view; and
a spacer portion overlapping the bank in the plan view and comprising the same material as the blocking portion.
